(19) United States
(12) Patent Application Publication
(10) Pub. No.: US 2023/0411314 A1
(43) Pub. Date: Dec. 21, 2023

(54) HIGH-EFFICIENCY STRUCTURES FOR IMPROVED WIRELESS COMMUNICATIONS

(71) Applicant: AKASH SYSTEMS, INC., San Francisco, CA (US)

(72) Inventors: Paul SAUNIER, San Francisco, CA (US); James CARROLL, San Francisco, CA (US); Martha YARBOROUGH, San Francisco, CA (US); Brian LORAN, San Francisco, CA (US); Daniel FRANCIS, San Francisco, CA (US); Larry WITKOWSKI, San Francisco, CA (US)

(21) Appl. No.: 18/048,373

(22) Filed: Oct. 20, 2022

Related U.S. Application Data
(63) Continuation of application No. PCT/US21/28927, filed on Apr. 23, 2021.
(60) Provisional application No. 63/014,247, filed on Apr. 23, 2020.
(60) Provisional application No. 63/056,013, filed on Jul. 24, 2020.
(60) Provisional application No. 63/056,376, filed on Jul. 24, 2020.

(51) Int. Cl. H01L 23/66; H01L 29/778

(52) U.S. Cl. CPC H01L 23/66; H01L 29/7786; H01L 2223/6644

(57) ABSTRACT

The present disclosure provides methods and systems of generating high-efficiency structures for improved wireless communications. Such structures may comprise hard and chemically inert materials. Such structures may include materials having average thermal conductivities equal to or greater than about 1,000 W/mK. Such structures may comprise diamond. Such structures may comprise materials whose properties may be affected through processing such structures. Such structures may comprise devices with improved electron mobilities and efficiencies. Such structures may comprise substrate features. Such features may be configured to communicatively couple to a device or a component of a substrate. A device may comprise a radio transmitter. Some examples include satellite transmitters.

### CROSS-REFERENCE

This application is a continuation application of PCT/US21/28927, filed Apr. 23, 2021, which claims the benefit of U.S. Provisional Application No. 63/014,247, filed Apr. 23, 2020, U.S. Provisional Application No. 63/056,013, filed Jul. 24, 2020, and U.S. Provisional Application No. 63/056,376, filed Jul. 24, 2020, each of which is incorporated herein by reference in its entirety.

### BACKGROUND

The ever-increasing demand for efficient high-frequency wireless communications has driven development in wide-bandgap semiconductor-based electronics in recent years. The advancement of new materials and device technologies are desired to improve thermal properties and power efficiencies of RF and microwave transistors, particularly for high-frequency communications and satellite communications. Further, advancements in processing methods of high-thermal conductivity structures are desired, including the development of methods to generate substrate features and components while avoiding damaging such structures and maintaining material quality during processing.

### SUMMARY

The present disclosure provides methods and systems of generating high-efficiency structures for improved wireless communications. Such structures may comprise hard and chemically inert materials. Such structures may include materials having average thermal conductivities equal to or greater than about 1,000 W/mK. Such structures may comprise materials whose properties may be affected through processing such structures. Such structures may comprise devices with improved electron mobilities and efficiencies. Such structures may comprise substrate features. Such features may be configured to communicatively couple to a device or a component of a substrate.

In an aspect, the present disclosure provides a device for transmitting or receiving signals. The device may comprise: a substrate comprising a material having an average value of thermal conductivity equal to or greater than about 1000 W/mK; at least one transistor comprising a material layer and operably connected to the substrate; and a feature disposed within at least a portion of the substrate, the feature having an average etch angle, as measured between a surface of the substrate and a sidewall of the feature, wherein the feature comprises an aspect ratio greater than or equal to about 1.25:1.

In some embodiments, the feature is disposed within at least a portion of the material layer. In some embodiments, the feature is a via. In some embodiments, the via is configured to couple the transistor to a surface of the substrate through the material layer and the substrate. In some embodiments, the etch angle is greater than or equal to about 80 degrees. In some embodiments, the etch angle is from about 86 degrees to about 90 degrees. In some embodiments, the feature comprises an aspect ratio greater than or equal to about 5:1. In some embodiments, the material layer comprises a wide-bandgap semiconductor material. In some embodiments, the transistor is a high electron mobility transistor. In some embodiments, the device is a radiofrequency amplifier module. In some embodiments, the device is a satellite transmitter.

In another aspect, the present disclosure provides a method of generating a feature in a structure comprising a substrate, wherein the substrate comprises a material having an average value of thermal conductivity equal to or greater than about 1000 W/mK. The method may comprise: providing the structure; and etching the substrate to remove at least a portion of the substrate, wherein the removal of the at least a portion of the substrate exposes a hollow region within the structure having an average etch angle, as measured between a surface of the structure and a sidewall of the hollow region.

In some embodiments, the structure comprises a semiconductor-containing material, and wherein the method further comprises etching a surface within the hollow region to remove at least a portion of the semiconductor-containing material. In some embodiments, the method comprises applying a laser to generate a modified region within the structure, the modified region comprising a modified crystalline structure of the structure at a plurality of focal depths from a surface of the structure, wherein the etching the substrate comprises removal of at least a portion of the modified region, and wherein the removal of the at least a portion of the modified region exposes the hollow region within the structure. In some embodiments, the structure comprises an etch mask disposed over at least a portion of the surface of the structure, and wherein the method further comprises applying the laser within an opening of the etch mask to generate the modified region within the structure. In some embodiments, structure comprises a metal pad disposed on a second surface of the structure, and wherein the method further comprises applying the laser such that the metal pad substantially overlaps, from the second surface, the modified region to be generated. In some embodiments, the etching comprises plasma etching. In some embodiments, etching comprises an etch selectivity within a range from about 10:1 to about 50:1. In some embodiments, the applying the laser comprises a laser power within a range from about 5 W to about 7 W. In some embodiments, the hollow region comprises an aspect ratio greater than or equal to about 1.25:1. In some embodiments, the hollow region comprises an aspect ratio greater than or equal to about 5:1. In some embodiments, the etch angle is greater than or equal to about 80 degrees. In some embodiments, the etch angle is within a range from about 86 degrees to about 90 degrees.

In another aspect, the present disclosure provides a semiconductor-containing layered structure. The semiconductor-containing layered structure may comprise: a substrate comprising a material having an average value of thermal conductivity equal to or greater than about 1,000 W/mK; at least one layer of a wide-bandgap semiconductor material disposed over the substate; and at least one layer of a semiconductor material disposed over and in contact with at least a portion of the wide-bandgap semiconductor material such that an interface region between the wide-bandgap semiconductor material and the semiconductor material exhibits a carbon peak at least about 1.5 times greater than an average carbon background of the layered structure as measured by secondary ion mass spectrometry.

In some embodiments, the at least one layer of the semiconductor material is a second layer of a wide-bandgap semiconductor material. In some embodiments, one or more of the at least one layer of the wide-bandgap semiconductor material or the second layer of the wide-bandgap semiconductor material comprises a material selected from the group consisting of GaN, AlN, InGaN, InAlN, AlGaN, InGaAlN, Ga2O3, ScAlN, and derivatives and combinations of thereof. In some embodiments, the at least one layer of the wide-bandgap semiconductor material and the second layer of the wide-bandgap semiconductor material comprise substantially the same material. In some embodiments, the second layer of the wide-bandgap semiconductor material is a regrowth layer. In some embodiments, the at least one layer of the wide-bandgap semiconductor material and the second layer of the wide-bandgap semiconductor material comprises substantially GaN. In some embodiments, the at least one layer of the semiconductor material has an average thickness within a range from about 500 Angstroms to about 1 micron. In some embodiments, the at least one layer of the semiconductor material has a surface leakage current less than about 10⁵ A at 10 V as measured by capacitance-voltage testing. In some embodiments, the substrate comprises diamond. In some embodiments, the at least one layer of the semiconductor material comprises a two-dimensional electron gas. In some embodiments, the at least one layer of the wide-bandgap semiconductor material and the at least one layer of the semiconductor material comprise a buffer layer of the layered structure.

In another aspect, the present disclosure provides a method of forming a compound semiconductor structure. The method may comprise: providing a semiconductor-containing layered structure in a chamber, the layered structure comprising at least one layer of a wide-bandgap semiconductor material and a substrate comprising a material having an average value of thermal conductivity equal to or greater than about 1,000 W/mK; generating at least one layer of a semiconductor material disposed over and in contact with at least a portion of the wide-bandgap semiconductor material, which generating comprises: heating the layered structure to a temperature greater than about 800° C.; and introducing a flow of one or more gases selected from a group consisting of Tri-methyl Gallium, Tri-methyl Aluminum, and nitrogen to deposit the at least one layer of the semiconductor material over the at least a portion of the wide-bandgap semiconductor material.

In some embodiments, the at least one layer of the semiconductor material comprises an average thickness within a range from about 500 Angstroms to about 1 micron. In some embodiments, the at least one layer of the semiconductor material comprises an average thickness of about 0.25 microns. In some embodiments, the method comprises, prior to providing the layered structure, cleaning a surface of the wide-bandgap semiconductor material. In some embodiments, the method comprises, prior to providing the layered structure, removing a portion of the wide-bandgap semiconductor material. In some embodiments, the removed portion comprises an average thickness within a range from about 500 Angstroms to about 1 micron. In some embodiments, the generating the at least one layer of the semiconductor material comprises generating a thickness of the semiconductor material that is substantially similar to the average thickness of the removed portion of the wide-bandgap semiconductor material. In some embodiments, the method comprises generating a layer of material disposed over the at least one layer of the semiconductor material to form a two-dimensional electron gas. In some embodiments, the at least one layer of the semiconductor material is a second layer of a wide-bandgap semiconductor material. In some embodiments, one or more of the at least one layer of the wide-bandgap semiconductor material or the second layer of the wide-bandgap semiconductor material comprises a material selected from the group consisting of GaN, AlN, InGaN, InAlN, AlGaN, InGaAlN, Ga2O3, ScAlN, and derivatives and combinations of thereof. In some embodiments, the at least one layer of the wide-bandgap semiconductor material and the second layer of the wide-bandgap semiconductor material comprise substantially the same material. In some embodiments, the at least one layer of the wide-bandgap semiconductor material and the second layer of the wide-bandgap semiconductor material comprise substantially GaN. In some embodiments, the method comprises generating the at least one layer of the semiconductor material in accordance with a surface property of a surface of the semiconductor material to be generated. In some embodiments, the surface property includes a surface leakage current. In some embodiments, the surface leakage current is less than about 10-Angstroms at 10 Volts as measured by capacitance-voltage testing. In some embodiments, the at least one layer of the semiconductor material comprises a two-dimensional electron gas. In some embodiments, the substrate comprises diamond.

In another aspect, the present disclosure provides a device. The device may comprise: a substrate comprising at least one layer of synthetic diamond; an intermediate layer adjacent to the substrate; a buffer layer disposed adjacent to the intermediate layer, wherein the buffer layer comprises a wide-bandgap semiconductor; and a barrier layer disposed adjacent to the buffer layer, wherein an interface between the barrier layer and the buffer layer comprises a heterojunction, and wherein the barrier layer comprises at least one layer of a material comprising scandium, aluminum, and nitrogen.

In some embodiments, the device comprises a gate contact in electrical communication with the barrier layer, a source contact in electrical communication with the barrier layer, and a drain contact in electrical communication with the barrier layer. In some embodiments, at least one of the source contact or the drain contact is in electrical communication with an n-type doped region within the barrier layer. In some embodiments, the gate contact is in electrical communication with a p-type doped region within the barrier layer. In some embodiments, the gate contact forms a Schottky contact with the barrier layer. In some embodiments, the intermediate layer comprises a nucleation layer for nucleating the at least one layer of synthetic diamond. In some embodiments, the device comprises a field effect transistor. In some embodiments, the field effect transistor is a junction field effect transistor. In some embodiments, the field effect transistor is a metal insulator semiconductor-type field effect transistor. In some embodiments, the field effect transistor is a high electron mobility transistor. In some embodiments, a distance from the two-dimensional electron gas layer to the substrate is less than 750 nanometers. In some embodiments, the buffer layer comprises one or more materials selected from the group consisting of gallium, aluminum, indium, boron, scandium, nitrogen, and derivatives thereof. In some embodiments, the device does not include the intermediate layer, and wherein the buffer layer and the substrate form a single interface.

In another aspect, the present disclosure provides a device. The device may comprise: a substrate comprising a material having a thermal conductivity equal to or greater than about 1,000 W/mK in at least a single dimension; a buffer layer disposed adjacent to the substrate, wherein the buffer layer comprises a semiconductor comprising a first Group III element and a first Group V element; and a barrier layer disposed adjacent to the buffer layer, wherein the barrier layer comprises scandium, a second Group III element, and a second Group V element, and wherein the barrier layer comprises a source region and a drain region, wherein the buffer layer and the barrier layer form a heterojunction at an interface between the buffer layer and the barrier layer.

In some embodiments, the source region comprises a source contact in electrical communication with the barrier layer, and wherein the drain region comprises a drain contact in electrical communication with the barrier layer. In some embodiments, at least one of the source region or drain region comprises an n-type doped region. In some embodiments, the device comprises a gate contact, wherein the gate contact is in electrical communication with a p-type doped region within the barrier layer. In some embodiments, the device comprises a gate contact, wherein the gate contact forms a Schottky contact with the barrier layer. In some embodiments, the device comprises an intermediate layer adjacent to the substrate, wherein the intermediate layer comprises a nucleation layer for nucleating the material of the substrate. In some embodiments, the device comprises a field effect transistor. In some embodiments, the field effect transistor is a junction field effect transistor. In some embodiments, the field effect transistor is a metal insulator semiconductor-type field effect transistor. In some embodiments, the field effect transistor is a high electron mobility transistor. In some embodiments, the device comprises a two-dimensional electron gas layer proximal to an interface between the buffer layer and the barrier layer. In some embodiments, a distance from the two-dimensional electron gas layer to the substrate is less than 750 nanometers. In some embodiments, the buffer layer comprises one or more materials selected from the group consisting of gallium, aluminum, indium, boron, scandium, nitrogen, and derivatives thereof. In some embodiments, the buffer layer and the substrate form a single interface.

In another aspect, the present disclosure provides a method of manufacturing a transistor. The method may comprise: forming a layered semiconductor structure comprising a buffer layer; generating a barrier layer adjacent to the buffer layer, wherein the barrier layer comprises at least one layer of a material comprising scandium, aluminum, and nitrogen; removing at least one layer of the layered structure; forming an intermediate layer disposed adjacent to the buffer layer after removing the at least one layer from the layered structure; and generating a synthetic diamond substrate disposed adjacent to the intermediate layer.

In some embodiments, the removing at least one layer from the layered structure comprises removing at least a portion of the buffer layer. In some embodiments, the intermediate layer comprises a nucleation layer for nucleating the synthetic diamond. In some embodiments, the removing at least one layer from the layered structure comprises chemical etching. In some embodiments, the layered structure comprises a buffer layer disposed, wherein the buffer layer comprises a semiconductor comprising an element from Group III and an element from Group V; and a barrier layer disposed adjacent to the buffer layer, wherein the barrier layer comprises at least one layer of a material comprising scandium, a second element from Group III, and an element from Group V. In some embodiments, the buffer layer comprises Gallium Nitride.

In another aspect, the present disclosure provides a method for forming a device. The method may comprise: (a) providing a layered semiconductor structure comprising a buffer layer; (b) removing at least a portion of the layered structure; (c) generating an intermediate layer adjacent to the buffer layer; (d) generating a synthetic diamond substrate disposed adjacent to the intermediate layer; and (e) generating a barrier layer adjacent to the buffer layer, wherein the barrier layer comprises at least one layer of a material comprising scandium, aluminum, and nitrogen.

In another aspect, the present disclosure provides a device for transmitting or receiving signals. The device may comprise: a substrate comprising synthetic diamond; at least one semiconductor layered structure operably connected to the substrate; and an etched via disposed within at least a portion of the substrate, the via comprising a hollow region connecting a first and a second side of one or more layers of the substrate.

In some embodiments, the via comprises a height of at least about 100 microns. In some embodiments, the via comprises an average etch angle, as measured between a surface of the substrate and a sidewall of the feature. In some embodiments, the via comprises an aspect ratio greater than or equal to about 1.25:1.

In another aspect, the present disclosure provides a satellite comprising: a housing; and the device of any aspect or embodiment disclosed herein.

In another aspect, the present disclosure provides a method of generating a feature in a substrate. The method may comprise: providing a substrate comprising synthetic diamond, the substrate comprising a semiconductor layered structure; and etching the substrate to form a via disposed within at least a portion of the substrate, the via comprising a hollow region connecting a first and a second side of one or more layers of the substrate.

In some embodiments, the hollow region has an average etch angle, as measured between a surface of the structure and a sidewall of the hollow region. In some embodiments, the via has an aspect ratio greater than or equal to about 1.25:1. In some embodiments, the semiconductor layered structure is a partially completed electronic device. In some embodiments, the semiconductor layered structure comprises a field effect transistor. In some embodiments, the method comprises etching a surface within the hollow region to remove at least a portion of the semiconductor layered structure. In some embodiments, the method comprises applying a laser to generate a modified region within the substrate or the semiconductor layered structure, the modified region comprising a modified crystalline structure at a plurality of focal depths. In some embodiments, the etching the substrate comprises removal of at least a portion of the modified region, and wherein the removal of the at least a portion of the modified region exposes the hollow region within the structure. In some embodiments, the substrate or the semiconductor layered structure comprises an etch mask disposed over at least a portion of the surface of the substrate or the semiconductor layered structure, and wherein the method further comprises applying the laser within an opening of the etch mask to generate the modified region within the substrate or the semiconductor layered structure. In some embodiments, the substrate or the semiconductor layered structure comprises a metal pad disposed on a second surface of the substrate or the semiconductor layered structure, and wherein the method further comprises applying the laser such that the metal pad substantially overlaps, from the second surface, the modified region to be generated. In some embodiments, the etching comprises plasma etching. In some embodiments, the etching comprises an etch selectivity within a range from about 10:1 to about 50:1. In some embodiments, the applying the laser comprises a laser power within a range from about 5 W to about 7 W. In some embodiments, the hollow region comprises an aspect ratio greater than or equal to about 1.25:1. In some embodiments, the hollow region comprises an aspect ratio greater than or equal to about 5:1. In some embodiments, the etch angle is greater than or equal to about 80 degrees. In some embodiments, the etch angle is within a range from about 86 degrees to about 90 degrees. In some embodiments, the method comprises disposing the substrate in a satellite. In some embodiments, the method comprises forming a field effect transistor on the substrate. In some embodiments, the method comprises forming a power amplifier comprising the semiconductor layered structure and the substrate.

Additional examples and advantages of the present disclosure will become readily apparent to those skilled in this art from the following detailed description, wherein only illustrative examples of the present disclosure are shown and described. As will be realized, the present disclosure is capable of other and different examples, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the present disclosure are set forth with particularity in the appended claims. A better understanding of the features and advantages of the present disclosure will be obtained by reference to the following detailed description that sets forth illustrative examples, in which the principles of the present disclosure are utilized, and the accompanying drawings or figures (also “FIG.” and “FIGs.” herein), of which.

FIG. 1 illustrates a cross-sectional view of an example structure, in accordance with some examples;

FIG. 2 illustrates a cross-sectional view of an example structure, in accordance with some examples;

FIG. 3 illustrates generally a cross-sectional view of an example method of generating a feature in a substrate, in accordance with some examples;

FIG. 4 illustrates generally a flow diagram of an example method of generating a feature in a substrate, in accordance with some examples;

FIG. 5A illustrates generally a cross-sectional view of an example method of generating a feature in a substrate, in accordance with some examples;

FIG. 5B illustrates generally a cross-sectional view of an example method of generating a feature in a substrate, in accordance with some examples;

FIG. 6A illustrates generally a flow diagram of an example method of generating a feature in a substrate, in accordance with some examples;

FIG. 6B illustrates generally a flow diagram of an example method of generating a feature in a substrate, in accordance with some examples;

FIG. 7 illustrates generally a flow diagram of an example method of generating a feature in a substrate, in accordance with some examples;

FIG. 8 illustrates generally a cross-sectional view of an example method of generating a feature in a substrate, in accordance with some examples;

FIG. 9 illustrates generally a cross-sectional view of an example method of generating a feature in a substrate, in accordance with some examples;

FIG. 10 illustrates generally a flow diagram of an example method of generating a feature in a substrate, in accordance with some examples;

FIG. 11 illustrates generally a flow diagram of an example method of generating a feature in a substrate, in accordance with some examples;

FIG. 12 illustrates generally a block diagram of an example device, in accordance with some examples;

FIG. 13 illustrates generally a cross-sectional view of an example method of generating a structure, in accordance with some examples;

FIG. 14 illustrates generally a cross-sectional view of an example method of generating a structure, in accordance with some examples;

FIG. 15 illustrates generally a cross-sectional view of an example method of generating a structure, in accordance with some examples; and

FIG. 16 illustrates a computer system that can be programmed or otherwise configured to form an example device, in accordance with some examples.

FIG. 17 illustrates a block diagram of an example system including one or more devices comprising a compound semiconductor substrate, in accordance with some embodiments disclosed herein.

FIG. 18 illustrates a block diagram of an example wireless device, in accordance with some embodiments disclosed herein.

FIG. 19 illustrates a block diagram of an example control-communications block of a wireless device, in accordance with some embodiments disclosed herein.

FIG. 20 illustrates a block diagram representing various examples of wireless communication networks, in accordance with some embodiments disclosed herein.

### DETAILED DESCRIPTION

While various examples have been shown and described herein, it will be obvious to those skilled in the art that such examples are provided by way of example only. Numerous variations, changes, and substitutions may occur to those skilled in the art without departing from the disclosure. It should be understood that various alternative examples described herein may be employed. It shall be understood that different examples may be appreciated or modified individually, collectively, or in combination with each other. Where values are described as ranges, it will be understood that such disclosure includes the disclosure of all possible sub-ranges within such ranges, as well as specific numerical values that fall within such ranges irrespective of whether a specific numerical value or specific sub-range is expressly stated.

Embodiments of the present disclosure provide semiconductor-containing structures with improved thermal and electrical properties and improved surface quality. Structures may comprise layers of wide-bandgap semiconductor materials. Materials may comprise Gallium Nitride (GaN). Materials may comprise Scandium (Sc).

The structures of the present disclosure may comprise substrate features, such as vias, interconnects and channels. Structures may comprise devices such as transistors. Transistors may include high-electron mobility transistor (HEMT) structures. Structures may comprise carbon-containing substrates. Structures may comprise substrates comprising materials having average thermal conductivities of about 1,000 Watts per meter Kelvin (W/mK) or greater. Structures may comprise electronic and optoelectronic device structures comprising ScₓAl₁₋ₓN alloys in combination with carbon-containing layers and/or substrates. Structures may comprise ScₓAl₁₋ₓN layers and substrates comprising GaN-on-diamond.

Disclosed are methods of forming features in high-thermal conductivity substrates. Such substrates may comprise hard or chemically inert materials, or a combination thereof. Such substrates may comprise films. Methods of forming features may reduce or eliminate damage to components, devices or materials proximate to the features and may reduce manufacturing time and complexity. Methods may improve etch selectivity in forming the features. Examples of apparatuses, devices and systems are provided comprising features with improved average feature sizes, average aspect ratios and average etch angles. Such features may be formed in close proximity to substrate components without causing damage to the components. Disclosed are structures and methods of forming the same having improved surface qualities (e.g., surface leakage current). Surface quality of a structure may be affected by exposure to high temperatures during formation, which may affect electrical properties of substrate surfaces.

Disclosed are structures that may comprise devices with improved current densities, improved operating voltages and improved thermal conductivities. Such devices may provide improved signal throughput and improved thermal management within wireless applications involving the transmission or reception of signals at L-band frequency ranges (e.g., 1-2 GHz), S-band frequency ranges (e.g., 2-4 GHz), C-band frequency ranges (e.g., 4-8 GHz), X-band frequency ranges (e.g., 8-12 GHz), K-band frequency ranges (e.g., Ku-band 17-20 GHz, Ka-band 37-40 GHz), V-band frequency ranges (e.g., 40-75 GHz), W-band frequency ranges (e.g., 75-110 GHz), millimeter wave (mmWave) frequencies (e.g., 60 GHz), E-band frequency ranges (e.g., 60-90 GHz), G-band frequency ranges (e.g., 110-300 GHz), or other suitable frequency ranges. Such devices may provide improved performance for high power and high frequency applications. Such devices may provide improved performance for satellite networks. For example, where performance may depend greatly on thermal conditions of a satellite transceiver.

Disclosed are devices such as amplifiers, transmitters, radios, satellites, and ground stations that may comprise one or more transistors as disclosed herein. Devices may deliver higher output powers for a same channel temperature and may provide improved power added efficiencies (PAE), compared to conventional semiconductor devices.

As recognized herein, generating features in substrates may be challenging when a substrate comprises physically hard or chemically inert materials. Examples of such materials may include materials having average thermal conductivities equal to or greater than about 1,000 W/mK in at least a single dimension. Some examples may include diamond. Such substrates may be impervious to wet chemical or plasma etching and may be resistant to laser drilling, mechanical drilling, and micromachining. Additionally, certain techniques, including laser ablation, may heat such substrates to temperatures that can damage surrounding components or materials. In addition to the foregoing challenges, such techniques can introduce lengthy processing times, which may negatively impact device production cycle. While high-energy plasma may be used to overcome a high covalent bond strength of certain substrate materials, the combination of high energy and slow etch speed may lead to poor etch selectivity. For example, a photomask defining a feature pattern may degrade or etch away during an etching process on substrates comprising materials that may be chemically inert. In such cases, mask patterns may be thick and robust to withstand degradation during etching, which may lead to extra processing steps, longer processing times and larger feature sizes.

The term “substrate,” as used herein, generally refers to any substance upon which a structure (e.g., layered structure) may be deposited. The substrate may comprise a foundation for the fabrication of electronic devices, such as transistors, diodes, and integrated circuits. A substrate may comprise at least a portion of a layered structure. A structure may comprise a substrate and at least a portion of a layered structure (e.g., compound semiconductor structure). A structure may comprise a device, such as a transistor. A transistor may comprise a material layer (e.g., at least a portion of a layered structure). The substrate may comprise a solid material such as a semiconductor or an insulator. Substrate materials may comprise one or more of, for example, carbon, aluminum, gallium, silicon, germanium, arsenic, thallium, cadmium, tellurium, selenium, scandium or alloy or allotrope thereof, or an oxide or nitride thereof. The substrate may be a carbon-containing substrate or a semiconductor-containing substrate. The substrate may include one or more chemical dopants, for example, nitrogen, phosphorous, boron or indium. Substrate materials may comprise one or more of, for example, diamond, synthetic diamond, silicon (Si), silicon dioxide (SiO₂), silicon carbide (SiC), aluminum oxide (Al₂O₃), sapphire, aluminum nitride (AlN), scandium aluminum nitride (ScAlN), germanium, gallium arsenide, gallium nitride (GaN), or indium phosphide (InP), indium nitride (InN), aluminum gallium nitride (AlGaN), indium gallium nitride (InGaN), indium aluminum nitride (InAlN), zinc oxide (ZnO), for example. The substrate may include carbon-containing materials such as diamond, synthetic diamond, diamond-like carbon (DLC), diamond nanoparticles (e.g., nanodiamond), graphite, graphene, etc. The substrate may include a material having a thermal conductivity (e.g., average thermal conductivity) equal to or greater than about 1,000 W/mK (e.g., in at least a single dimension). The average thermal conductivity of such substrate may be greater than at least about 500 W/mK, 1,000 W/mK, 1,500 W/mK, 2,000 W/mK, 2,500 W/mK, 3,000 W/mK or greater. The average thermal conductivity may be from about 500 W/mK to about 2,000 W/mK. The average thermal conductivity may be from about 500 W/mK to about 3,000 W/mK. The average thermal conductivity may be from about 1,500 W/mK to about 2,500 W/mK. Such materials may be “high-thermal conductivity” materials. The substrate may include a wide-bandgap semiconductor. The substrate material may be single crystalline, poly crystalline, amorphous or a combination thereof. The substrate may comprise a buffer layer. The substrate may comprise a barrier layer. The substrate may comprise a buffer layer disposed adjacent to the barrier layer. An intermediate layer may be disposed between the buffer layer and the barrier layer. The buffer layer may comprise a wide-bandgap semiconductor. The buffer layer may comprise a Group III element and a Group V element. The barrier layer may comprise a wide-bandgap semiconductor. The barrier layer may comprise a Group III element and a Group V element. The barrier layer may comprise a source region and a drain region. The buffer layer and the barrier layer may include a channel between the source region and the drain region.

The term “single-crystal,” as used herein may refer to a material having one crystal or having a translational symmetry. The term “polycrystalline” generally refers to a material having more than one crystal domain or orientation. A polycrystalline material may exhibit more than one crystal structure under low energy electron diffraction (LEED) microscopy. The term “amorphous” generally refers to a material having no real or apparent crystalline form. An amorphous material may not exhibit any long-range crystal structure under LEED.

The term “layered structure,” as used herein, generally refers to structures created from layers materials of varying properties. A layered structure may comprise layers of the same or varying semiconductor properties. Individual layers may be single crystalline or polycrystalline. Individual layers may be amorphous. Electronic and optoelectronic devices manufactured out of layers of different semiconductor properties may be made by different growth techniques. In some cases, these growth techniques may allow for controlled growth of individual layers. In some case, the layers may be referred to as “epitaxial layers” or “epilayers.” Each layer may be of a thickness varying from sub-nanometer to tens of microns. Each layer may be of a thickness between 1 nanometer (nm) and 50 nm, between 10 nm and 100 nm, etc. Each layer may be greater than 1 nm, 2 nm, 5 nm, greater than 10 nm, 20 nm, greater than 50 nm, greater than 100 nm, greater than 1 micron or greater. Each layer may be less than 1 micron, less than 100 nm, less than 50 nm, less than 20 nm, less than 10 nm, less than 5 nm, less than 2 nm, less than 1 nm, or less. Each layer may be atomically thin. Non-limiting examples of manufacturing techniques include molecular beam epitaxy (MBE), chemical vapor deposition (CVD), atomic layer deposition (ALD), physical vapor deposition, organo-metallic vapor-phase epitaxy, and liquid phase epitaxy.

A substrate may comprise a thickness of at least about 1 micron, at least about 10 microns, at least about 50 microns, at least about 100 microns, at least 1 about millimeter or greater. A substrate may comprise a thickness of at least 1 millimeter of diamond. A substrate may comprise a thickness of diamond from about 1 micron to about 1 millimeter, from about 10 microns to about 1 millimeter, from about 50 microns to about 1 millimeter or from about 100 microns to about 500 microns. A substrate may comprise a thickness of about 100 microns, about 105 microns, about 110 microns, about 125 microns, about 150 microns, or greater.

Epitaxial layers may comprise one or more of, for example, boron, aluminum, gallium, indium, thallium, carbon, silicon, germanium, tin, lead, nitrogen, phosphorous, arsenic, antimony, bismuth, oxygen, sulfur, selenium, tellurium, beryllium, magnesium, calcium, zinc, cadmium, scandium, and alloys and allotropes thereof or an oxide or nitride thereof. Epitaxial layers may comprise a semiconductor comprising a bond between at least one Group III element and at least one Group V element. Epitaxial layers may comprise semiconductors comprising a bond between nitrogen and at least one Group III element (e.g., boron, aluminum, gallium, indium, thallium, scandium), semiconductors comprising a bond between carbon and at least one group IV element (e.g., carbon, silicon, germanium, tin, lead), and semiconductors comprising a bond between oxygen and at least one group II element (e.g., beryllium, magnesium, calcium, zinc, cadmium). Epitaxial layers may comprise one or more wide-bandgap semiconductors. Epitaxial layers may comprise one or more of, for example, GaN, AlN, InN, AlGaN, ScAlN, InGaN, InAlN, ZnO, SiC, and diamond. Any of the above materials may be single-crystalline, polycrystalline, or amorphous.

The term “wide-bandgap” and “wide-gap” (or variations thereof), as used herein in the context of semiconductor technology, generally refer to electronic and/or optoelectronic devices and manufacturing technologies based on wide-bandgap semiconductors. A wide-bandgap semiconductor may have a bandgap in a range of 2-4 electronvolt (eV), for example. In some examples, a wide-bandgap semiconductor may have a bandgap in a range greater than about 3.4 eV. A wide-bandgap semiconductor can comprise, for example: (a) semiconductors comprising a bond between nitrogen (N) and at least one Group III element from the Periodic Table of the Elements, (b) semiconductors comprising a bond between carbon (C) and at least one Group IV element from the Periodic Table of the Elements, or (c) semiconductors comprising a bond between oxygen (O) and at least one Group II element from the Periodic Table of the Elements.

The term “interface,” as used herein, generally refers to a surface forming a common boundary between two different materials, for example, materials having different crystalline structures, differing material combinations or, differing material properties. The term “interface” can refer to a location where two different materials come into contact with one another. The term “interface” can also refer to the atoms of a first material combining with the atoms of a second material at a location or at a boundary, for example, substantially without the presence of atoms of a third material. In some examples, an interface may be a surface forming a common boundary between a semiconductor and diamond. A substrate comprising at least two different materials may include a single interface (e.g., surface forming a boundary between the two materials). In some examples, a substrate may not include more than one interface. An interface may not include a nucleation layer. An interface may comprise a material that is discontinuous across a substrate surface. For example, an interface may comprise a discontinuous layer of material. A discontinuous material may comprise diamond seeds.

The term “intermediate layer,” as used herein, generally refers to a material layer disposed between two material layers, for example, between two layers of materials having similar or varying properties. Intermediate layers may comprise single crystalline, polycrystalline or amorphous materials. Intermediate layers may comprise wide-bandgap semiconductors. Intermediate layers may comprise carbon-containing materials. Individual layers surrounding an intermediate layer may comprise materials having different lattice-constants or different lattice structures. Individual layers surrounding an intermediate layer may comprise materials having different thermal conductivities and/or different sheet resistivities. An intermediate layer may comprise an interface or interface layer between two material layers. An intermediate layer may have a thickness from about sub-nanometer to tens of microns. An intermediate layer may have a thickness from about 20 nm to about 2,000 nm. An intermediate layer may have a thickness from about 1 nm to about 200 nm or greater. An intermediate layer may have a thickness greater than about 1 nm, 2 nm, 5 nm, greater than 10 nm, 20 nm, greater than 50 nm, greater than 100 nm, greater than 1 micron or greater. An intermediate layer may have a thickness less than about 1 micron, less than 100 nm, less than 50 nm, less than 20 nm, less than 10 nm, less than 5 nm, less than 2 nm, less than 1 nm, or less. An intermediate layer may have a thickness from about 1 nm to about 150 nm, about 150 nm or greater than 150 nm. An intermediate layer may be thinned by a method such as mechanical polishing or etching.

An intermediate layer may comprise a transition layer between two material layers or two substrates. In some examples, a transition layer may bridge a first lattice structure (e.g., first lattice constant) of a first material layer to a second lattice structure (e.g., second lattice constant) of a second material layer. One or more transition layers may be used to accommodate for a change in the lattice constants and help absorb dislocations between two material layers or substrates.

An intermediate layer may comprise a nucleation layer. The term “nucleation layer” or “nucleating layer,” as used herein, may generally refer to a layer that assists in starting the growth or formation of another layer of material or stoichiometry. Nucleating layer materials may include silicon or wide-bandgap semiconductor materials. Nucleation layers may help prevent etching or damage to an underlying material, upon which another material is nucleated. In some examples, a nucleation layer may aid in the nucleation of diamond on a semiconductor-containing substrate, while preventing damage to the substrate which may occur through the growth conditions of diamond (e.g., high temperature).

In some examples, an intermediate layer between two materials may not include a nucleation layer. An intermediate layer may comprise a material that is discontinuous across a substrate surface. For example, an intermediate layer may comprise a discontinuous layer of material. A discontinuous material may comprise diamond seeds.

For example, substrate seeding for synthetic diamond growth may be achieved through ultrasonic seeding, a process that can include placing a substrate in an ultrasonic seeding solution or bath (e.g., containing diamond particles) and agitating the bath until the diamond particles adhere to the substrate. Manufacturing compound semiconductor substrates that include synthetic diamond presents certain challenges. For example, diamond deposition is a high-temperature process often requiring temperatures greater than about 600° C. (e.g., about 800° C.) and the use of highly reactive gases such as atomic hydrogen. Such temperatures and reactive gases (e.g., H2) may be incompatible with many semiconductors and may damage or cause defects to a semiconductor material, resulting in performance degradation of semiconductor structures and devices, among other drawbacks. Additionally, differing lattice constants between diamond and semiconductors may present challenges to integrating diamond with semiconductor devices. Bonding or die attachment methods have been common methods of integrating diamond heat sinks with semiconductor devices and circuits.

Some alternatives to bonding and die-attachment may also address the concern of damage to a semiconductor material during diamond growth. Some alternatives may include selective area deposition (SAD) and the use of nucleating layers or nucleating materials for nucleating diamond on semiconductor materials. Some alternatives may include the use of selective area nucleation.

SAD can include using photoresist (or other materials) as sacrificial layers to seed and grow diamond over a semiconductor structure. SAD may also include applying nucleation layers between photoresist coatings to define areas for diamond growth on a substrate. In some cases, during ultrasonic seeding, diamond particles may adhere to the photoresist (or a nucleating material) instead of a surface of a semiconductor structure and diamond may be grown over the semiconductor structure from the seeded diamond particles in the photoresist or other material.

Nucleating layer(s) may be disposed between two material layers or substrates, such as two material layers having similar or varying properties. A nucleating layer may have similar properties to a material to which the nucleating layer assists in the growth of. In some examples, a nucleating layer may comprise nucleation material that is added to a final stage of growth of another material layer, such as a semiconductor structure (e.g., final stage of epitaxial growth), in which case the nucleation material may not necessarily be an independent layer but may be integrated into the other material layer near a surface of the material layer (e.g., top surface). In some examples, growth of synthetic diamond can include a nucleation phase in which a nucleating layer and diamond-growth conditions can enhance nucleation of diamond on a host substrate. For example, in the case of vapor deposition (e.g., CVD), diamond-growth conditions can include conditions within a vacuum chamber.

Active layers of a semiconductor device may be epitaxially grown on a substrate. In some examples, the substrate may be of the same family of materials as the active layers of the electronic device. Electronic materials for device fabrication may be realized by attaching the active layers to substrates comprising materials having crystalline structures and material combinations different from the active layer. Examples of ways to attach semiconductors with different crystal structures to other substrates can include direct-bonding and direct growth. Direct growth can include using intermediate layer(s) to bridge different lattice structures. Alternatives to bonding and die-attachment may include the use of selective area deposition (SAD).

The substrate may have various functions, including but not limited to (i) mechanical support; (ii) electrical conductivity that can be used to connect the active layers to the bottom of the chip; (iii) electrical isolation with low dielectric losses that can be used in high-frequency devices and surface waveguides where electric fields penetrate into the substrate; and (iv) high thermal conductivity with or without associated electrical conductivity.

The term “chip,” as used herein generally refers to an active electronic and/or optical device disposed on a substrate. As used herein, a chip may comprise an active device (or layer(s)) and a substrate. The active electronic or optical device may comprise a layered structure. The chip may comprise one or more transistors (e.g., FET, bipolar transistor). The one or more transistors may comprise one or more high-electron-mobility transistors. The chip may comprise an integrated circuit. In some examples, the chip may perform functions such as mixing, power amplification, low noise amplification, and switching. In some examples, the chip may comprise a monolithic microwave integrated circuit (MMIC).

The term “transistor,” as used herein, generally refers to an electrical device which can act as a switch and/or an amplifier. A transistor may be a part of a digital circuit. A transistor may be part of an analog circuit. A transistor may be one of a plurality of transistors. A transistor may comprise a layered structure as described elsewhere herein. A transistor may be a part of a computing device. A transistor may be a portion of a logic circuit or a logic gate. A transistor may be a part of a radiofrequency device. A transistor may be a semiconductor device.

The term “field-effect transistor” (FET) as used herein, generally refers to a transistor which uses an electric field to control the operation of a device having the transistor. A FET may include a source, a drain and a gate. An electric field may be used to control the flow of current (electrons or holes) between two contacts or terminals in the device such as a source contact and a drain contact. A “bipolar junction transistor” (BJT) may comprise an emitter, collector and a base.

The term “high-electron-mobility transistor” (HEMT), as used herein, generally refers to a field-effect transistor comprising a heterojuction. A high-electron-mobility transistor may be alternatively referred to as a heterostructure field effect transistor.

The term “heterojunction,” as used herein, generally refers to the interface between any two solid-state materials of differing material properties. In some examples, these may include any two semiconductors, any two crystalline forms (including amorphous and polycrystalline forms) of the same semiconductor, any two semiconductors comprising the same element but with varying amounts of those elements, any two semiconductors with varying dopant level, etc. The two materials may have unequal band gaps. The two materials may have a band offset. The two materials forming the heterojuction may be referred to as a “heterostructure.” As described herein, the interface between the buffer layer and the barrier layer may form a heterojunction.

The term “Schottky contact,” as used herein, generally refers to a metal-semiconductor interface with a non-zero contact resistance, measured relative to the resistance of the semiconductor. The contact may comprise an energetic barrier between states of the semiconductor and states of the metal which barrier may be non-zero. The contact may be a rectifying contact, e.g., a Schottky barrier. In some examples, devices may include one or more dielectric or insulating material layers, for example, under a gate contact. Such devices may comprise Metal-Insulator-Semiconductor Field Effect Transistors (“MISFET”s).

The term “substrate property,” as used herein may include surface leakage current, as measured in Amps (A). Other substrate properties may include charge density, thermal boundary resistance, thermal conductivity, electrical conductivity, electrical resistivity, or defect density. A substrate property may be measured by capacitance-voltage (C-V) testing. Other methods of measuring substrate properties may include four-point probe conductivity measurement, sheet resistance measurement tools, non-contact sheet resistance measurements, Eddy current measurement, laser flash, Fourier Transform Infra-Red (FTIR) analysis, Time Domain Thermal Reflectance (TDTR). A substrate property may be measured at a temperature of about 23° C. A substrate property may be measured by scanning electron microscopy (SEM) or by transmission electron microscopy (TEM).

The term “regrowth layer,” “regrown layer,” “regrowth material,” or similar terms, may include a material or a layer of material that is grown on another material. A regrowth layer may be a material that is grown on an epitaxial layer or an epitaxial structure. The regrowth layer and the material upon which the regrowth layer is grown may have similar properties to one another. A portion of a semiconductor material may be removed (e.g., from an epitaxial structure or a substrate) and a regrowth layer may be generated over a surface of the semiconductor material. The regrowth layer may be similar in thickness to the removed portion of the semiconductor material. The regrowth layer may comprise a similar material to the semiconductor material from which the portion is removed. A surface of a semiconductor material may comprise a modified crystalline structure of the semiconductor material and removal of the portion of the semiconductor material may include removing a portion of or substantially all of the modified crystalline structure. In some examples, modified crystalline structures may affect surface properties, for example, surface leakage currents (A). In some examples, removal of a portion of a semiconductor material that includes modified crystalline structures and regrowth of an additional layer of semiconductor material generates a surface that is better suited for device fabrication.

The term “thermal budget,” as used herein, generally refers to an assessment of temperature dissipation from one or more components to an environment. For example, a thermal budget may define an amount of thermal energy transferred from a heat source (e.g., active layers of a device) to a surrounding environment. The active layers of a semiconductor device may be several micrometers thick and may be disposed adjacent to mechanical carriers or substrates.

The term “substrate feature” or “feature,” as used herein, may generally refer to a vertical interconnection access (“via”), channel or singulation trench in a substrate, for example. A “via” or “through-substrate via” (or variations thereof) as used herein, may generally refer to an electrical connection disposed between layers in a substrate, such as a layered semiconductor-containing structure. A via may couple a first layer of the substrate to a second layer of the substrate, a first device or circuit to second device or circuit, or to an antenna, or other component, for example. A via may couple a top or front side of a substrate to a bottom or back side of the substrate. A via may couple a via pad on a first side of the substrate to a metal layer on a second side of the substrate, for example, to provide electrical ground to a device disposed on or within the substrate or a layered structure.

A feature may comprise a hollow region within a substrate. A hollow region in a substrate, for example, may be generated at least in part by etching modified substrate material. Etching modified substrate material may result in removal of the material. The substrate material may be modified using a laser, as described herein. The hollow region may continue through more than one layer of the substrate, including more than one material. A feature may also comprise a hollow region in a substrate, including one or more substrate layers, that may be plated with an electrically conductive material, such as a metal. Such feature may communicatively couple two or more layers of the substrate. A plating within a feature may have a thickness of less than or equal to about 4 microns, at least 1 micron, at least 4 microns, at least 5 microns, at least 6 microns, at least 12 microns, at least 15 microns, or greater. A plating within a feature may have a thickness from about 1 micron to about 4 microns, from about 4 microns to about 6 microns, from about 6 microns to about 12 microns, from about 12 microns to about 15 microns, or greater.

A feature may comprise an average feature size. An average feature size may be characterized by parameters including an average height, and average width or average diameter, an average aspect ratio and an average etch angle. A feature may be round or rectangular shaped. A feature may comprise another geometry (e.g., octagon). A feature height may be defined by a substrate thickness or layer thickness of a layer in the substrate. A feature may have a width or diameter of at least about 1 micron, at least about 10 microns, at least about 20 microns, at least about 30 microns, at least about 40 microns, at least about 50 microns, at least about 60 microns or greater. A feature may have a width or diameter of less than or equal to about 20 microns. A feature may have a width or diameter of less than or equal to about 40 microns. A feature may have a width or diameter from about 1 micron to about 100 microns, from about 10 microns to about 100 microns, from about 20 microns to about 100 microns, from about 30 microns to about 100 microns or from about 40 microns to about 100 microns, from about 60 microns to about 100 microns or greater. A feature may have a width or diameter from about 10 microns to about 40 microns, from about 10 microns to about 60 microns or greater. A feature may have a height varying from sub-nanometer to hundreds of microns. A feature may have a height less than or equal to about 150 microns. A feature may have a height of at least about 1 micron, at least about 25 microns, at least about 50 microns, at least about 100 microns or greater.

A feature may be characterized by an “aspect ratio” or “average aspect ratio.” In some examples, an aspect ratio (e.g., an average aspect ratio) may generally refer to a ratio between a height of a feature and a width or diameter of the feature (e.g., height-to-width aspect ratio). For example, a substrate feature having a height of 100 microns and a diameter or width of 20 microns may have an aspect ratio of 5:1, 5/1 or 5. As another example, a feature having a height of 50 microns and a width of 40 microns may have an aspect ratio of 1.25:1 or 1.25. A feature may have an aspect ratio of at least about 0.25:1. A feature may have an aspect ratio of at least about 1:1, at least about 1.25:1, at least about 2:1, at least about 3:1, at least about 4:1, at least about 5:1, at least about 7:1, at least about 10:1 or greater.

In some examples, an aspect ratio may generally refer to a ratio between a first width or diameter of a feature and a second width or diameter of the feature (e.g., width-to-width aspect ratio). For example, an aspect ratio may refer to a ratio between a width or diameter of a feature on a first surface of a substrate and a width or diameter of the feature on a second surface of the substrate. In some examples, a feature may comprise a first width or diameter on a backside surface of a substrate and a second width or diameter on a frontside surface of the substrate. The backside surface, the frontside surface, or both, may comprise a material having an average thermal conductivity equal to or greater than about 1,000 W/mK. The backside surface, the frontside surface, or both, may comprise diamond. The frontside surface may comprise an interface between diamond and another material different from diamond. The frontside surface may comprise another material different from diamond, for example, a semiconductor containing material.

A substrate may comprise one or more features that may be disposed proximate to a device or component of the substrate, such as a transistor. In some examples, such components may be disposed on a surface of the substrate. Components may also be disposed within a substrate, such as within epitaxial layers of a substrate. Methods disclosed herein provide improved distances (e.g., average distances) between such features and components, for example, shorter distances between a features and components compared to standard methods. In some examples, a distance between a feature and a component may be defined by a distance between a surface or edge of the component and a surface of the feature (e.g., inner surface). A distance between a feature and a component may be, for example, less than or equal to about 50 microns, less than or equal to about 40 microns, less than or equal to about 30 microns, less than or equal to about 20 microns, less than or equal to about 15 microns, or less. A distance between a feature and a component may be from about 30 microns to about 20 microns, from about 20 microns to about 10 microns, from about 10 microns to about 5 microns, or less.

The term “etching,” as used herein, generally refers to a process of removing (e.g., via chemical or gas etchant) one or more layers from a wafer or substrate. A portion of the substrate may be protected from etching by the use of an “etch mask,” which may comprise material that resists etching. Etch mask materials may include, for example, silicon nitride, silicon dioxide, aluminum, titanium, gold, nickel, or copper. Etching may include wet etching (e.g., using chemical etchants). Etching may include dry etching (e.g., using plasma or gas etchants), also known as plasma etching. Plasma etching may, for example, include microwave plasma etching, hydrogen plasma etching, reactive-ion etching (RIE), ion-assisted chemical vapor etching, inductively coupled plasma (ICP), transformer-coupled plasma (TCP) or capacitively coupled plasma (CCP). A plasma etcher, or etching tool, may be used to plasma etch a substrate. An etching tool may produce a plasma source (e.g., etching species) from a gas (e.g., O₂, fluorine-bearing gas) and an electric field (e.g., RF, microwave, DC). An etching species may comprise positively charged or negatively charged ions. Etching quality may be influenced in part by parameters including selectivity, uniformity, directionality, plasma density and etching rate. Plasma density may be determined by plasma process parameters such as plasma etch power, process pressure and gas flow rate.

Plasma etching may include the use of a single power source or multiple power sources. For example, a plasma etching process may include the use of a first power source (e.g., plasma power source) to generate a plasma source or etching species and a second power source to apply to a wafer or substrate. The second power source (e.g., bias power source) may, for example, be used to generate a charge (e.g., bias) on a surface of the substrate to modify a reaction between the etching species a material of the substrate. For example, a second power source may be used to generate a positive charge on the substrate which may accelerate etching through a reaction with a negatively charged etching species. An amount of power used for the first power source may be a “plasma power” and an amount of power used for the second power source may be a “bias power.”

The term “plasma power,” as used herein, may generally refer to an amount of power provided by a power source (e.g., plasma power source) to generate plasma. An excitation frequency, such as a radiofrequency (RF) excitation may be applied to a plasma power source to generate plasma at a certain frequency (e.g., 13.56 MHz, 2.45 GHz). Excitation frequency may affect plasma discharge characteristics and etching characteristics, in part, by affecting a spatial distribution of plasma species, electric field across plasma discharge and electron energy distribution. Uniformity of etching may be characterized in part by an evenness of etching across a substrate and a degree of etching rates maintained through the process of etching a substrate, or multiple substrates in a reactor. A power source used for a plasma etching process may vary according to, and may be limited by, the plasma etching tool used. A power source may also vary according to tool geometry and power handling capability. In some examples, a power source may be less than or equal to about 25 W. In some examples, a power source may be at least about 25 W, at least about 100 W, at least about 300 W, at least about 600 W, at least about 1,000 W, at least about 2,000 W or greater. Plasma etch power may be from about 25 W to about 100 W, from about 100 W to about 300 W, from about 300 W to about 600 W, from about 600 W to about 1,000 W, from about 1,000 W to about 3,000 or greater.

The term “etch angle” or “average etch angle,” as used herein, generally refers to an angle between a first surface, which may comprise an unetched area, and a second surface comprising an etched area. For example, an etch angle may be defined by an angle between a surface of a substrate and a surface within a feature or within a hollow region of the substrate. An etch angle may be defined by an angle between a surface of the substrate and a surface within an etched area of the substrate. In some examples, an etch angle may be defined as an angle between a surface of a diamond substrate and a surface of an etched feature (e.g., via) within the diamond substrate. An etch angle may, for example, be less than about 80 degrees. An etch angle may be less than or equal to about 80 degrees. An etch angle may be at least about 80 degrees, at least about 84 degrees, at least about 86 degrees, at least about 88 degrees or greater. An etch angle may, for example, be from about 80 degrees to about 84 degrees, from about 84 degrees to about 86 degrees, from about 86 degrees to about 88 degrees, from about 88 degrees to about 90 degrees or from about 86 degrees to about 90 degrees. An etch angle may be greater than about 90 degrees.

An etching process may be characterized by parameters including, for example, etch rate, etch time, etch selectivity, and etch power (e.g., plasma power). An etch rate, for example, may be less than or equal to about 0.4 microns per minute (um/min). An etch rate may be at least about 0.4 um/min, at least about 0.5 um/min, at least about 1 um/min or at least about 1.5 um/min or greater, for example. An etch rate may, for example, be from about 0.25 um/min to about 0.4 um/min, from about 0.4 um/min to about 0.5 um/min, from about 0.4 um/min to about 1 um/min, from about 0.5 um/min to about 1 um/min, from about 1 um/min to about 1.5 um/min or from about 0.5 um/min to about 1.5 um/min. An etch time may, for example, may be less than or equal to about 1 hour. An etch time may be about 2 hours, about 4 hours, about 10 hours or greater. An etch time may be at least about 2 hours, at least about 4 hours, at least about 10 hours or greater. An etch time may be from about 2 hours to about 4 hours, from about 4 hours to about 6 hours or from about 6 hours to about 10 hours.

The term “etch selectivity ratio,” “etch selectivity,” or “selectivity” (or variations thereof), as used herein, may generally refer to a ratio between an etch rate of a first material and an etch rate of a second material. For example, an etch selectivity ratio may be defined as a ratio between an etch rate of a substrate material and an etch rate of an etch mask material, or vice versa. An etch selectivity ratio may also be defined as a ratio between a rate of etching of a first portion of a substrate and a rate of etching of a second portion of a substrate. An etch selectivity ratio may be less than or equal to about 6:1. A selectivity may be at least about 6:1, at least about 10:1, at least about 20:1, at least about 25:1, at least about 50:1 or greater. A selectivity may be in a range from about 6:1 to about 20:1, from about 20:1 to about 25:1, from about 25:1 to about 50:1, from about 10:1 to about 50:1, or greater.

In some aspects, devices comprising scandium-based barrier layers (e.g., ScₓAl₁₋ₓN) may improve AlGaN transistor charge density and consequently current density Jₘₐₓ (A/mm). An alloy comprising ScₓAl₁₋ₓN may have a stable hexagonal structure and may be lattice-matched to GaN. In some aspects, scandium-based barrier layers may not be lattice matched to buffer layers. Films comprising ScₓAl₁₋ₓN may be grown on GaN and SiC epitaxial layers. Increasing scandium composition (e.g., of a barrier layer) may increase piezoelectric response relative to AlN and may enhance the spontaneous polarization. An increase in piezoelectric and spontaneous polarization may increase the maximum current density Jₘₐₓ in a device. Polarization discontinuity between a material layer comprising scandium (e.g., barrier layer) and a material layer comprising GaN (e.g., channel) may provide higher surface electron densities compared to non-scandium devices. A device comprising a scandium-based barrier layer and a GaN channel may have a lower sheet resistivity compared to non-scandium devices.

In an example, consider an RF amplifier operating in class A having an AlGaN transistor at the output stage. The amplifier may deliver output RF power, P_{RF}, and exhibit power gain G (=P_{RF}/P_{IN}, where P_{IN} is input RF power). Overall power-efficiency η of this amplifier may be defined as

$$η = \frac{{P}_{out} - ( {P}_{in} )}{{P}_{DC}} or \frac{{P}_{out} - ( {P}_{out} / G )}{{P}_{DC}} \qquad ( 1 )$$

where P_{DC}=½Iₘₐₓ/V_{DD} is the power delivered from the power supply with voltage V_{DD} and ½Iₘₐₓ is the average DC current flowing into the later stages of the amplifier, assuming that the current in the transistor varies from zero to Iₘₐₓ. In this example, the dissipation in the driver stage may be assumed to be negligible relative to the dissipation in the output stage, for the sake of simplicity. In this example, the highest efficiency η for class A may be 50%; however, the efficiency may be higher for amplifier classes operating with reduced conduction angle, where the average DC current through transistor is lower than ½Iₘₐₓ. If we assume that the amplifier gain G is large (G>>1), the efficiency t may be approximately equal to the ratio P_{RF}/P_{DC}. The power P_{DISS} dissipated into heat at the output stage is approximately equal to P_{RF} (1/η−1). The operating temperature of the output transistor T_{CH} (channel temperature) relative to the temperature of the back of the amplifier package (top of heatsink) T_{HS} is given by T_{CH}=T_{HS}+K·P_{DSS}, where K is the thermal resistance in degrees per Watt of the output transistor. By keeping the transistor geometry fixed and increasing the current carrying capability Iₘₐₓ, the RF output power PF can be increased. The increase in current carrying capability Iₘₐₓ of the transistor may slightly and indirectly improve the transistor efficiency η, and η may be assumed to remain unchanged. In this example, the channel temperature is given by:

$${T}_{CH} = {T}_{HS} + K \cdot {P}_{DISS} = {T}_{HS} + K \cdot {P}_{RF} ( \frac{1}{η} - 1 ) \qquad ( 2 )$$

As shown above, increase in RF output power capability of a transistor may directly increase the channel temperature, and hence the benefits of using higher current carrying capability Iₘₐₓ may be reduced unless the thermal resistance is simultaneously reduced and the overall efficiency is improved. Additionally, the overall efficiency may reduce as the device temperature rises, and hence reduction in the thermal resistance may also help maintain or improve the overall efficiency of the amplifier.

Devices comprising scandium-based barrier layers may provide improved Jₘₐₓ values, lower thermal resistances, and improved power handling. Substrates comprising wide-bandgap semiconductors and high thermal conductivity materials (e.g., carbon-based materials such as diamond, synthetic diamond, diamond-like carbon (DLC), graphene, graphite, etc.) may provide improvements in operating temperatures for scandium-based devices. Devices may include scandium-based barrier layers, GaN-based buffer layers and diamond substrates.

Examples of the present disclosure may include etching substrate features in substrates comprising high-thermal conductivity materials, for example, diamond. Etching may include dry etching, such as plasma etching. Plasma etching may include reactive-ion etching (RIE) and inductively coupled plasma (ICP). Plasma etching diamond substrates may include the use of an etch mask. Plasma etching may include applying a set of selected etching parameters, for example, a plasma power, a bias power, and an excitation frequency. Plasma etching a diamond substrate may comprise using a plasma power from about 500 W to about 3000 W and a bias power from about 50 W to about 1000 W. A plasma excitation frequency may be from about 10 MHz to about 50 MHz. A diamond substrate may be plasma etched at a rate from about 0.5 microns per minute to about 1.5 microns per minute with an etch selectivity from about 10:1 to about 50:1.

Examples of the present disclosure may include laser processing a substrate. Some examples include laser processing a substrate prior to etching substrate features. Some examples include the use of a laser to modify a substrate material. Modifying of the substrate may include a change to a crystalline structure of a substrate material. Modifying may include damaging the crystalline structure of the substrate material. Laser processing may include, for example, laser ablation, laser grooving, laser breaking or die attach film laser cutting. Such laser processing methods may introduce substrate particle contaminants or debris contaminants, unwanted cracks or damage to components disposed on or within a substrate. In some examples, a laser beam may be focused at a depth (e.g., focal depth) below a surface of the substrate (e.g., within a substrate interior) to generate an area of modified crystalline structure (e.g., modified region, defect region). The area of modified substrate material may be within or between one or more layers of the substrate. A focal depth may be from sub-nanometer to tens of microns. For example, a focal depth may be from about 1 nanometer (nm) to about 50 nm, from about 10 nm to about 100 nm, from about 100 nm to about 1 micron, from about 1 micron to about 50 microns, from about 50 microns to about 100 microns or greater.

The laser may be moved (e.g., scanned) across a substrate surface to generate an area of modified substrate material within the substrate. The laser may be scanned in a scanning direction parallel to the substrate surface. The laser may be applied to a back side of the substrate. The laser may be applied to a front side of the substrate. A back side of the substrate may comprise diamond. The laser processing may include parameters including, but not limited to, average laser power (W), pulse energy (μJ), pulse wavelength (nm), pulse frequency (kHz) and laser scanning speed (mm/s). An average laser power may, for example, be less than or equal to about 1 W, from about 1 W to about 1.5 W, from about 1.5 W to about 3 W, from about 3 W to about 7 W or greater. A pulse energy may, for example, be less than or equal to about 1 μJ, from about 1 μJ to about 4 μJ, from about 4 μJ to about 7 μJ, from about 7 μJ to about 15 μJ or greater. A wavelength may, for example, be less than or equal to about 1,000 nm, from about 1,000 nm to about 1,100 nm, from about 1,100 nm to about 1,300 nm or greater. A scanning speed may, for example, be less than or equal to about 100 mm/s, from about 100 mm/s to about 150 mm/s, from about 150 mm/s to about 200 mm/s or greater. A pulse frequency may, for example, be less than or equal to about 100 kHz. A pulse frequency may be equal to about 100 kHz or greater. A laser process may include the use of a Nd:YAG laser. Other lasers may be used, for example, according to a relationship between laser wavelength and energy band gap of a substrate material.

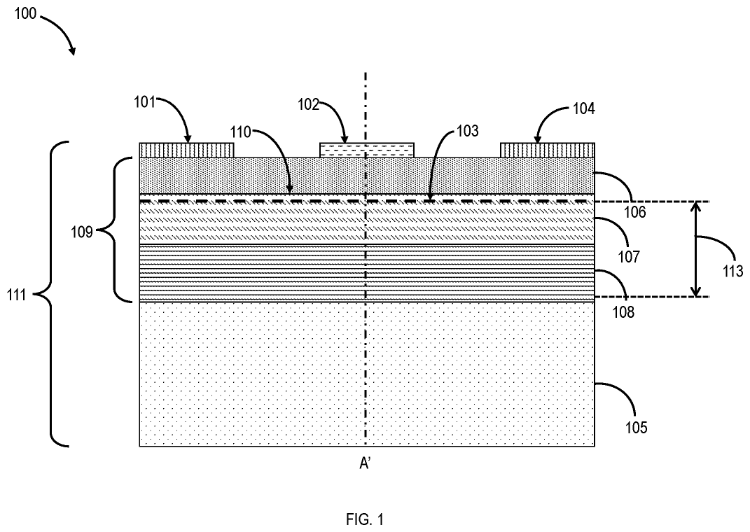

FIG. 1 illustrates a cross-sectional view of an example compound semiconductor structure 100, in accordance with some aspects. Structure 100 may comprise a substrate. Structure 100 may comprise a device (e.g., 111). Device 111 may comprise a transistor. Device 111 may comprise an integrated circuit or chip, such as a MMIC chip. Device 111 may comprise a HEMT. Device 111 may comprise one or more epitaxial layers. One or more layers of the epitaxial layers may be grown on another substrate which may not be shown in FIG. 1. Such epitaxial layers may collectively form a layered structure 109. The layered structure 109 may comprise one or more layers of a wide-bandgap semiconductor. The layered structure 109 may comprise an intermediate layer 108. The intermediate layer 108 may comprise a nucleation layer, for example, for nucleating growth of the substrate 105. In some examples, the intermediate layer 108 does not comprise a nucleation layer. The intermediate layer 108 may comprise a material that is discontinuous across a substrate surface. The layered structure 109 may comprise a buffer layer 107 and a barrier layer 106. The layered structure 109 may comprise a thickness of about 750 nm. The layered structure 109 may comprise a thickness from about 300 nm to about 3,000 nm. Device 111 may also comprise contacts, for example, a source 101, gate 102, and drain 104. Device 111 may comprise a heterostructure (e.g., heterojunction), for example, formed at interface 110. In some aspects, layered structure 109 may comprise a two-dimensional electron gas (2DEG) layer (e.g., 2DEG channel), which may be embedded within the layered structure 109.

Device 111 may comprise a substrate 105. The substrate 105 may comprise a high thermal conductivity material. Such material may have a thermal conductivity of at least about 1,000 W/mK. The substrate 105 may comprise diamond (e.g., synthetic diamond). The substrate 105 may comprise a thickness of at least 1 micron of diamond. The substrate 105 may comprise a thickness of diamond of at least about 1 micron, at least about 10 microns, at least about 50 microns, at least about 100 microns, at least 1 about millimeter or more. The substrate 105 may comprise a thickness of at least 1 millimeter of diamond. The substrate 105 may comprise a thickness of diamond from about 1 micron to about 1 millimeter, from about 10 microns to about 1 millimeter, from about 50 microns to about 1 millimeter or from about 100 microns to about 500 microns.

The substrate 105 may be generated on another substrate which may not be shown in FIG. 1. The intermediate layer 108 may comprise a nucleation layer and the substrate 105 may be nucleated on a surface of the nucleation layer. The nucleating layer may comprise nucleating material that is imbedded within the buffer layer 107 (e.g., added in a final growth stage of the buffer layer 107) and the substrate 105 may be generated on a surface of a nucleating material. The device 111 (e.g., layered structure 109) may not comprise a nucleating layer or nucleating material and the substrate 105 may be generated on a surface of the layered structure 109 without the use of a nucleating layer or nucleating material. In such aspects, the substrate 105 and a surface of the layered structure 109 may form a single interface. The substrate 105 may be generated on a surface of the buffer layer 107. The layered structure 109 may comprise a structure generated from layers of materials of varying properties.

The thickness of the intermediate layer 108 may be equal to or less than about 150 nm, less than about 100 nm, less than about 50 nm, less than about 25 nm, less than about 10 nm, less than about 5 nm, or less than about 1 nm. The intermediate layer 108 may be thinned. The intermediate layer 108 may comprise a semiconductor, for example, a semiconductor comprising silicon, a semiconductor comprising a bond between nitrogen and at least one Group III element, a semiconductor comprising a bond between at least one Group III element and at least one Group V element, a semiconductor comprising a bond between carbon and at least one group IV element, a semiconductors comprising a bond between oxygen and at least one group II element, or a semiconductor comprising a bond between silicon and at least one Group III, IV, or V element. The intermediate layer 108 may be single-crystalline, polycrystalline, or amorphous.

The layered structure 109 may comprise a heterostructure. The heterostructure may comprise the barrier layer 106 and the buffer layer 107. The barrier layer 106 and the buffer layer 107 may comprise materials having unequal band gaps. The barrier layer 106 and the buffer layer 107 may comprise materials having a band offset. The buffer layer 107 may comprise a 2DEG layer 103, for example, proximate to interface 110. The two-dimensional electron gas layer may be proximate to the interface between the barrier layer 106 and the buffer layer 107. The density of the electrons in the 2DEG (e.g., channel) may determine the resistance between the source and the drain and may be controlled with the voltage applied to the gate terminal. The channel and locations proximate to the source, gate, and drain contacts may be sources of heat.

The width of the 2DEG layer 103 may be controlled through the application of a voltage. The width of the 2DEG layer 103 may be less than 50 nm, less than 10 nm, or less than 5 nm. In some examples, the 2DEG layer 103 may be no further than 150 nm, no further than 250 nm, no further than 500 nm, no further than 750 nm, no further than 1 micron or no further than 100 microns from an edge of the substrate 105. In some examples, the 2DEG layer 103 may be about 730 nm from an edge of the substrate 105. In some examples, the 2DEG layer 103 may be no further than 200 nm, no further than 300 nm, no further than 1,000 nm, no further than 2,000 nm or no further than 3,000 nm from an edge of the substrate 105.

The buffer layer 107 and the barrier layer 106 may comprise a wide-bandgap semiconductor (e.g., III-V semiconductor, a III-III′-V semiconductor). The buffer layer 107 may comprise GaN, and the barrier layer 106 may comprise ScAlN. The buffer layer 107 may comprise a III-V semiconductor of a first dopant level and the barrier layer 106 may comprise a III-V semiconductor of a second dopant level. The buffer layer 107 may comprise a III-III′-V semiconductor of a first dopant level and the barrier layer 106 may comprise a III-III′-V semiconductor of a second dopant level. The buffer layer 107 may comprise one or more epitaxial layers adjacent and between the barrier layer 106 and the transition layer 108 (or alternatively, the substrate 105). The buffer layer 107 may comprise one of two sides of a heterojunction. The buffer layer 107 may comprise gallium and nitrogen. The buffer layer 107 may comprise one or more materials selected from the group consisting of gallium, aluminum, indium, boron, scandium, nitrogen and derivatives thereof. The buffer layer 107 may comprise GaN. The buffer layer 107 may comprise one or more materials selected from the group consisting of GaN, AlN, InGaN, InAlN, AlGaN, InGaAlN, Ga2O3 and derivatives thereof. The buffer layer 107 may comprise a thickness of less than about 1 micron, 750 nm, 500 nm, 250 nm, 100 nm, 50 nm, 10 nm, 5 nm, or less. The buffer layer 107 may be grown on a layered structure and subsequently thinned by a method such as mechanical polishing or etching. A thinned buffer layer may have a thickness of less than about 150 nm.

The barrier layer 106 may comprise one or more epitaxial layers adjacent and between the buffer layer 107 and the source, gate, and drain. The barrier layer 106 may comprise one of two sides of a heterojunction. The barrier layer 106 may comprise ScAlN. The barrier layer 106 may comprise a thickness less than about 150 nm, 100 nm, 50 nm, 10 nm, 5 nm, or less. The barrier layer 106 may be grown on a layered structure and subsequently thinned. A thinned barrier layer may have a thickness of less than about 150 nm. The barrier layer 106 may comprise a ScₓAl₁₋ₓN alloy and the value X may be from about 0.01 to about 0.99, from about 0.1 to about 0.9, from about 0.05 to about 0.4, or from about 0.05 to about 0.3. X may be equal to about 0.2, less than about 0.2, less than 0.25, less than 0.3, less than 0.4, less than 0.55, less than 0.6, less than 0.8, or less than 0.9.

The device 111 may comprise a source contact (e.g., 101), a gate contact (e.g., 102), and a drain contact (e.g., 104). The contacts may comprise a metal disposed adjacent to the barrier layer 106 and a Schottky barrier may be located at the boundary between the gate metal 102 and the barrier layer 106. An insulating or dielectric layer may be disposed adjacent to the gate contact. The device may be a MIS-type device or a MISFET. The Schottky barrier height (in eV), the thickness of the barrier layer 106, and the composition of the barrier height may determine the amount of charge in the channel. For AlGaN, electron concentrations may be from about 1×10¹² cm⁻² to about 1×10¹³ cm⁻² and electron concentrations may be a factor in determining maximum linear current density Jₘₐₓ (A/mm) through the device 111.

The barrier layer 106 may comprise a source region and a drain region. A region near an electrical contact (e.g., source region, drain region) may be etched and may comprise a material that is regrown in the region, such as a n-type material, and such region may comprise a regrown ohmic contact. A p-type material layer may be disposed adjacent or proximate to a gate contact. The source region may comprise a first n-type doped region, which may be in electrical communication with a source contact. The drain region may comprise a second n-type doped region, which may be in electrical communication with a drain contact. The device 111 may comprise a gate contact forming a Schottky contact with the barrier layer 106. The device 111 may comprise at least one dielectric layer disposed adjacent to the gate contact.

The barrier layer 106 may be adjacent to buffer layer 107 forming heterojunction 110 at which a polarization charge may be present, and this charge in combination with the conduction-band band offset at the heterojunction 110 may form a 2DEG channel 103 with center plane of charge distribution located a small distance away from the heterojunction 110. The center of charge distribution of the 2DEG channel 103 evaluated in a direction perpendicular to the substrate 105 may be a curved surface which may be substantially parallel to the surface of the substrate 105.

FIG. 1 may illustrate an example structure of a field-effect transistor (FET). The FET may comprise metal gate contact terminal 102, the barrier layer 106, the buffer layer 107, the intermediate layer 108, and the substrate 105. The distance 113 may be defined as the distance between the center of charge distribution evaluated in the direction perpendicular to the surface of substrate 105 below the center of a gate contact terminal 102 and top surface of the substrate 105. The distance 113 and the materials chosen for buffer layer 107 and intermediate layer 208, disposed between a heat source located at the 2DEG channel 103, and the substrate 105 may be parameters for determining a thermal resistance of the FET. The distance 113 may be modified to achieve a decrease in thermal resistance of the FET. For example, the distance 113 may be modified to a distance that may be no further than about 3,000 nm, no further than about 2,000 nm, no further than about 1,000 nm, no further than about 750 nm (e.g., about 730 nm), no further than about 500 nm, no further than about 300 nm, no further than about 250 nm, from about 750 nm to about 150 nm, or less than about 150 nm. This distance may be determined based on the mechanical properties of the materials and process-related constraints.

The 2DEG channel 103 may be characterized by a center plane of charge distribution at a distance from a surface of the substrate 105. The shortest distance between the substrate 105 and the source contact or the drain contact may be less than or equal to about 800 nm, 300 nm, 200 nm, 150 nm, 100 nm, 50 nm, 40 nm, 30 nm, 20 nm, 10 nm, or less. In some examples, a thermal conductivity measured from a barrier layer adjacent one of a plurality of contacts to the substrate may be at least about 500 W/m*K, at least about 1000 W/m*K, at least about 1500 W/m*K, at least about 2000 W/m*K, or greater than 2000 W/m*K.

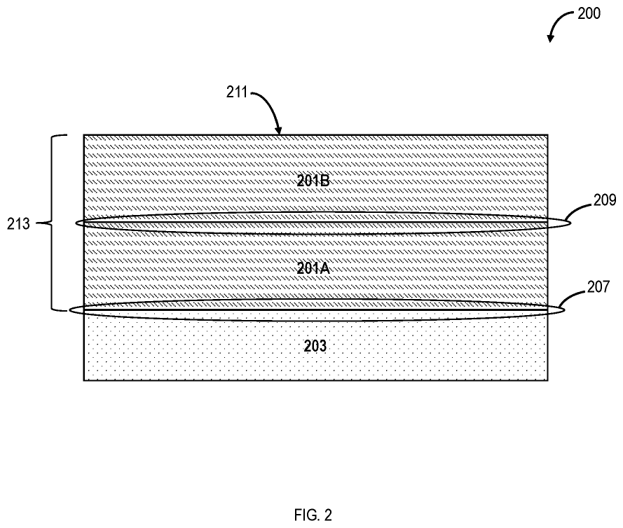

FIG. 2 illustrates a cross-sectional view of an example structure 200, in accordance with some examples. Structure 200 may comprise a substrate. In some examples, structure 200 may comprise one or more similar elements to the elements of structure 100. Structure 200 may include a substrate 203, material 201A and material 201B. In some examples, the substrate 203 may be a thermally conductive substrate, as described herein. For example, the substrate 203 may comprise a material having an average value of thermal conductivity equal to or greater than about 1,000 W/mK. The substrate 203 may comprise diamond. The material 201A may be a semiconductor-containing material. The material 201A may comprise a wide-bandgap semiconductor material. The material 201A may comprise a material including one or more of GaN, AlN, InGaN, InAiN, AlGaN, InGaAlN, Ga2O3, ScAlN, and derivatives and combinations of thereof. The material 201A may comprise substantially GaN.

An interface 207 between the substrate 203 and the material 101A may be a single interface. The interface 207 may comprise a single interface in which at least a portion of the substrate 203 is in contact with at least a portion of the material 201A. The interface 207 may comprise a nucleation layer or a nucleation material. The substrate 203 and material 201A may comprise a layered structure in which at least a portion of the substrate 203 has been formed over at least a portion of the material 201A. The interface 207 may comprise an intermediate layer. The interface 207 may comprise a discontinuous layer of material, as described herein. The substrate 203 may comprise a thickness as described herein.

The material 201A may be formed on a growth substrate (not shown). One or more transition layers may be used in the growth of the material 201A (not shown). Transition layers may be removed prior to the growth of the substrate 203. The material 201A may be flipped and disposed onto a carrier substrate (not shown). The material 201A may be disposed onto a carrier substrate prior to generating the substrate 203 on the material 201A.

The material 201B may be a semiconductor-containing material. The material 201B may comprise a wide-bandgap semiconductor material. The material 201B may comprise a material including one or more of GaN, AlN, InGaN, InAlN, AlGaN, InGaAlN, Ga2O3, ScAlN, and derivatives and combinations of thereof. The material 201B may comprise substantially GaN. The material 201B may comprise substantially SiN. In some examples, material 201A and material 201B may comprise substantially the same material. For example, material 201A and material 201B may comprise substantially GaN.

The material 201B may be formed over a surface of material 201A. A portion of the material 201A may be removed prior to generating the material 201B. A removed portion of the material 201A may comprise an average thickness from about 500 Angstroms to about 1 micron. A thickness of the material 201B may be substantially similar to a thickness of a removed portion of the material 201A. The material 201B may be a regrowth layer that comprises a substantially similar material to the material 201A. As a regrowth layer, the material 201B may also comprise a thickness substantially similar to a thickness of a removed portion of the material 201A or a thickness substantially similar to a remaining thickness of the material 201A, after the removal of the portion of the material 201A.

An interface 209 between the material 201A and the material 201B may comprise at least a portion of the material 201B in contact with at least a portion of the material 201A. An interface property of interface 209 may be measured, for example, using secondary ion mass spectrometry (SIMS). The interface 209 may exhibit a carbon peak using SIMS. The interface 209 may exhibit a carbon peak at least about 1.5 times greater than an average carbon background of one or more of the material 201A, the material 201B or the substrate 203, as measured by SIMS. The interface 209 may comprise an N-face surface of the material 201A. A region of the material 201A proximate to the interface 209 may comprise a higher concentration of nitrogen atoms compared to a region of the material 201A proximate to the interface 207.

The surface 211 may comprise substantially the material 201B, and the surface 211 may comprise surface properties that are beneficial for the formation of electronic devices, such as transistors. Formation of such devices may include the deposition of one or more additional semiconductor materials over a portion of the surface 211 of the material 201B. The surface 211 may comprise a surface leakage current, for example, that may be less than a threshold value. The surface 211 may comprise a surface leakage current less than about 10⁻⁵ A, less than 10⁻⁷ A, less than 10⁻⁸ A, less than 10⁻¹⁰ A, or less, from about 10⁻⁵ A to about 10⁻⁷ A, from about 10⁻⁷ A to about 10⁻¹⁰ A, from about 10⁻¹⁰ A to about 10⁻¹² A, or less. The structure 200 may comprise a 2DEG layer. Material 201B may comprise a 2DEG layer. A 2DEG layer may comprise one or more additional layers of material not shown. The material 201A and the material 201B may form a buffer layer of the structure 200. The structure 200 may include a barrier layer, which is not shown in FIG. 2 for simplicity.

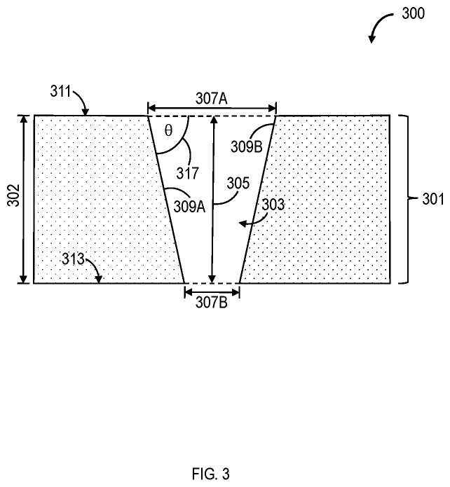

FIG. 3 illustrates a cross-sectional view of an example structure 300, in accordance with some examples. Structure 300 may comprise a substrate. Structure 300 may comprise one or more similar elements to the elements of structure 100 or structure 200. Structure 300 may comprise substrate material 301. Structure 300 may comprise a height 302. Structure 300 may comprise a feature 303, which may be a feature as described herein, for example, a via or channel. The feature 303 may comprise a height (e.g., 305) and a width (or diameter) (e.g., 307A or 307B). A feature height may be similar to the substrate height 302 or may be a fraction of a substrate height (e.g., less than substrate height 302). The feature 303 may comprise sidewalls 309A and 309B. The width of the feature 303 may vary according a location of measurement within the substrate, for example, feature 303 may comprise a first width 307A at a location proximate to a first surface 311 of the structure 300 and a second width 307B at a location proximate to a second surface 313 of the structure 300. Other widths of the feature 303 may be from width 307A to 307B depending on a location of measurement, for example, depending on a depth within the structure 300 relative to a surface (e.g., 311, 313) of the structure 300. For example, the feature 303 may have a width of at least about 1 micron, at least about 10 microns, at least about 20 microns, at least about 30 microns, at least about 40 microns, at least about 50 microns, at least about 60 microns or greater. A feature may have a width of less than or equal to about 20 microns. A feature may have a width of less than or equal to about 40 microns. The feature 303 may be characterized in part by an aspect ratio. The aspect ratio of feature 303 may be defined by a ratio of the height 305 of the feature 303 to the width or diameter 307B (or 307A). In some examples, the aspect ratio may be greater than about 1.25:1. The aspect ratio may from about 1.25:1 to about 5:1, or greater. The aspect ratio may be from about 1.25:1 to about 11:1. An aspect ratio of feature 303 may be defined by a ratio of a first width or diameter (e.g., 307A) to a second width or diameter (e.g., 307B).

The feature 303 may comprise a hollow region within the structure 300. The feature 303 may comprise a hollow region with sidewalls (e.g., 309A, 309B). The sidewalls may be plated with an electrically conductive material. The thickness of the plating may be from about 1 micron to about 4 microns, for example. The feature 303 may comprise an etch angle 317. Etch angle 317 may comprise an angle measured from a surface (e.g., sidewall 309A) of the feature 303 to the horizontal (e.g., horizontal plane located proximate to surface 311 of the structure 300). The etch angle 317 may be greater than or equal to about 80 degrees. The etch angle 317 may be from about 86 degrees to about 90 degrees, for example.

Substrate material 301 may comprise a semiconductor-containing material. Substrate material 301 may comprise a wide-bandgap semiconductor. In some examples, structure 301 may be formed on a separate growth substrate (not shown). The substrate material 301 may include one or more layers. One or more layers of the structure 300 may be removed (e.g., by etching or mechanical polishing).

Substrate material 301 may comprise a high-thermal conductivity material. Substrate material 301 may have an average thermal conductivity of at least about 1,000 W/mK in at least a single dimension (e.g., vertical dimension, horizontal dimension). The thermal conductivity may be greater than at least about 50 W/mK, 100 W/mK, 500 W/mK, 1,000 W/mK, 2,000 W/mK, 3,000 W/mK, or more. The thermal conductivity may be from about 500 W/mK to about 2,000 W/mK. The thermal conductivity may be from about 500 W/mK to about 3,000 W/mK. The thermal conductivity may be from about 1,500 W/mK to about 2,500 W/mK. The structure 300 may be a carbon-containing substrate. The structure 300 may comprise at least one layer of diamond (e.g., synthetic diamond). A synthetic diamond substrate may comprise chemical vapor deposited diamond.

The structure 300 may comprise a thickness of at least 1 micron of diamond. The structure 300 may comprise a thickness of diamond of at least about 1 micron, at least about 10 microns, at least about 50 microns, at least about 100 microns, at least 1 about millimeter or more. The structure 300 may comprise a thickness of at least 1 millimeter of diamond. The structure 300 may comprise a thickness of diamond from about 1 micron to about 1 millimeter, from about 10 microns to about 1 millimeter, from about 50 microns to about 1 millimeter or from about 100 microns to about 500 microns.

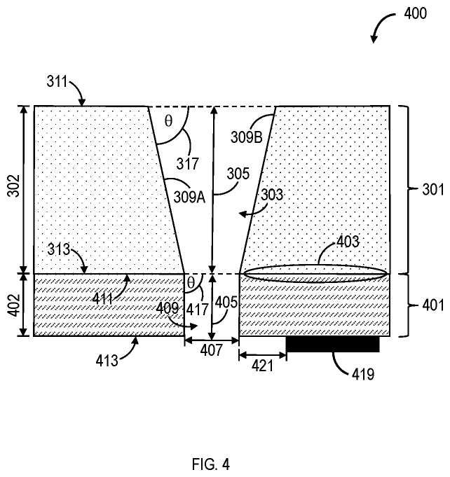

FIG. 4 illustrates a cross-sectional view of an example structure 400, in accordance with some examples. Structure 400 may comprise a substrate. Structure 400 may be a compound substrate. Structure 400 may be a layered structure. Structure 400 may include properties and elements similar to those described with respect to structure 100, 200 or 300. Structure 400 may comprise material 401, which may have a height 402. Material 401 may comprise a combination of more than one material and may comprise one or more layers. Material 401 may comprise a semiconductor, such as a wide-bandgap semiconductor. The wide-bandgap semiconductor material may comprise a material selected from the group consisting of GaN, AlN, InGaN, InAlN, AlGaN, InGaAlN, Ga2O3, ScAlN, and derivatives and combinations thereof. Material 401 may comprise GaN.

The structure 400 may include one or more intermediate layers or transition layers. The structure 400 may include a nucleation layer between material 301 and 401. Material 401 may include nucleation material. A nucleation layer or nucleation material may be used for nucleating material 301 on the material 401. The nucleation layer may be deposited on a surface of material 401 and diamond may be generated on a surface of the nucleation layer. In some examples, structure 400 may not comprise a nucleating layer or nucleating material and the material 301 may be generated on a surface of the material 401 without the use of a nucleating layer or nucleating material. In such examples, the material 301 may be in contact with at least a portion of the surface of material 401 at interface 403. In some examples, interface 403 may comprise one or more discontinuous material layers. The material 401 may comprise a structure generated from layers of materials of varying properties, as described herein. A material 401 may comprise layers, each layer comprising varying semiconductor properties. Individual layers may be single crystalline. The layers may be generated using different growth techniques. The growth techniques may allow for controlled growth of individual layers. Growth techniques may include the use of intermediate layers to attach layers having varying material properties (e.g., lattice structures or lattice constants).

The material 401 may comprise a heterostructure. The heterostructure may comprise a barrier layer and the buffer layer. The barrier layer and the buffer layer may comprise materials having unequal band gaps. The barrier layer and the buffer layer may comprise materials having a band offset. Structure 400 may comprise a comprise a two-dimensional electron gas layer (2DEG layer) (not shown), which may be embedded within the structure 400, such as within material 401. The 2DEG layer may be embedded within the buffer layer. The 2DEG layer may be proximate to an interface between the barrier layer and the buffer layer. The 2DEG layer may have a width of less than 50 nm, less than 10 nm, or less than 5 nm. The 2DEG layer may be equal to or less than 750 nm from an edge of the material 301. The 2DEG layer may be equal to or less than about 250 nm, about 500 nm, about 750 nm, about 1 micron or about 100 microns from an edge of the material 301.

The buffer layer may comprise a thickness of less than about 1 micron, less than about 750 nm, less than about 500 nm, or less than about 250 nm. In some examples, the buffer layer may comprise a thickness from 250 nm to 1 micron. In some examples, the buffer layer may comprise a thickness from 50 nm to 750 nm. The buffer layer may have a thickness of less than about 100 nm, less than about 50 nm, less than about 10 nm, or less than about 5 nm. The buffer layer may have a thickness that is from about 1 nm to about 150 nm. The barrier layer may comprise a thickness less than about 150 nm. A barrier layer may have a thickness of less than about 100 nm, less than about 50 nm, less than about 10 nm, or less than about 5 nm. The barrier layer 106 may have a thickness that is from about 1 nm to about 150 nm.

Structure 400 may comprise a component 419. In some examples, component 419 is communicatively coupled to a device. In some examples, component 419 comprises an interconnect for a device. In some examples, component 419 comprises a terminal or metal pad for communicatively coupling to an interconnect, a device or both. The terminal may communicatively couple to a source, drain or gate of a transistor. The terminal may communicatively couple to a collector or emitter of a transistor. In some examples, component 419 comprises patterned metal for communicatively coupling to an interconnect, a device or both. A device may be epitaxially grown on structure 400, as described herein. The component 419 may comprise, or may communicatively couple to, a device (e.g., passive or active). The component 419 may comprise, or may communicatively couple to, one or more transistors (e.g., FET, HEMT, MISFET, etc.). The component 419 may comprise, or may communicatively couple to, an integrated circuit, such as a MMIC. The component 419 may comprise, or may communicatively couple to a device, such as a transistor or an amplifier (e.g., power amplifier).

The material 401 may comprise a feature 409, which may be a feature as described herein, for example, a via or channel. The feature 409 may be coupled to feature 303. Feature 409 and feature 303 may each be at least part of a feature in the structure 400, for example, feature 409 and feature 303 may comprise a via through structure 400. The feature 409 and the feature 303 may comprise a channel in the structure 400. Feature 409 may comprise sidewalls that may be plated with an electrically conductive material. The feature 303 and the feature 409 may together communicatively couple one side of structure 400 to another side of structure 400, for example, a back side to a front side. In some examples, the feature 303 and the feature 409 may together communicatively couple an electrical ground from one side of structure 400 to a component or device on another side of structure 400. The feature 409 may comprise a height (e.g., 405) and a width or a diameter 407. A feature height may be similar to the material height 402 or may be a fraction of material height 402 (e.g., less than material height 402). The width or diameter of the feature 409 may vary according a location of measurement within the material 402, for example, feature 409 may comprise a first width at a location proximate to a first surface 411 of the material 401 and a second width at a location proximate to a second surface 413 of the material 401. Other widths of the feature 409 may be depending on a location of measurement, for example, depending on a depth within the material 401 relative to a surface (e.g., 411, 413) of the material 401. In some examples, a width of the feature 409 may be similar to the width of the feature 303. In some examples, the feature 409 may comprise a hollow region within the material 401. In some examples, the feature 409 may comprise a hollow region with sidewalls, which may be plated with an electrically conductive material.

The feature 409 may comprise an etch angle 417. Etch angle 417 may comprise an angle measured from a surface (e.g., sidewall) of the feature 409 to the horizontal. The horizontal may be measured from a horizontal plane proximate to the surface 411 of material 401 or surface 313 of material 301, for example. The feature 409 may be characterized in part by an aspect ratio. The aspect ratio of the feature 409 may be defined by a ratio of the height 405 to the width or diameter 407. In some examples, an aspect ratio of the feature 409 may be defined by a ratio of a first width or diameter (e.g., 407) to a second width or diameter (not shown).

The methods disclosed herein of manufacturing features may provide smaller distances between devices and features compared to standard feature manufacturing processes, at least in part, because of decreased or eliminated damage to such devices during manufacturing. In examples where a device is a transistor, the transistor may use a voltage applied between a gate and a source to control current flowing along the 2DEG between the source and a drain. A region of the 2DEG (e.g., an active region) (not shown) where the gate voltage controls the current may be located below the gate. A barrier layer, a buffer layer or both (not shown) may be adjacent to the 2DEG and together they may comprise material 401. Structure 400 may comprise a distance between a component or device and an edge of a feature. For example, a feature (e.g., 409, 303 or both) may be generated at a distance 421 from a component 419. In some cases, the feature 409 or 303 is disposed distance 421 from an edge of a device and the component 419 is a component (e.g., metal pad, terminal, etc.) of the device located closest to the edge of the feature (e.g., 409 or 303). The distance 421 may, for example, be less than or equal to about 50 microns, less than or equal to about 40 microns, less than or equal to about 30 microns, less than or equal to about 20 microns, less than or equal to about 15 microns, or less. A distance between a feature and a component may be from about 30 microns to about 20 microns, from about 20 microns to about 10 microns, from about 10 microns to about 5 microns, or less.

The example methods described herein may include additional or even fewer operations or processes in comparison to what is illustrated. Additionally, examples of the methods described are not necessarily limited to the chronological order that is shown in such figures.

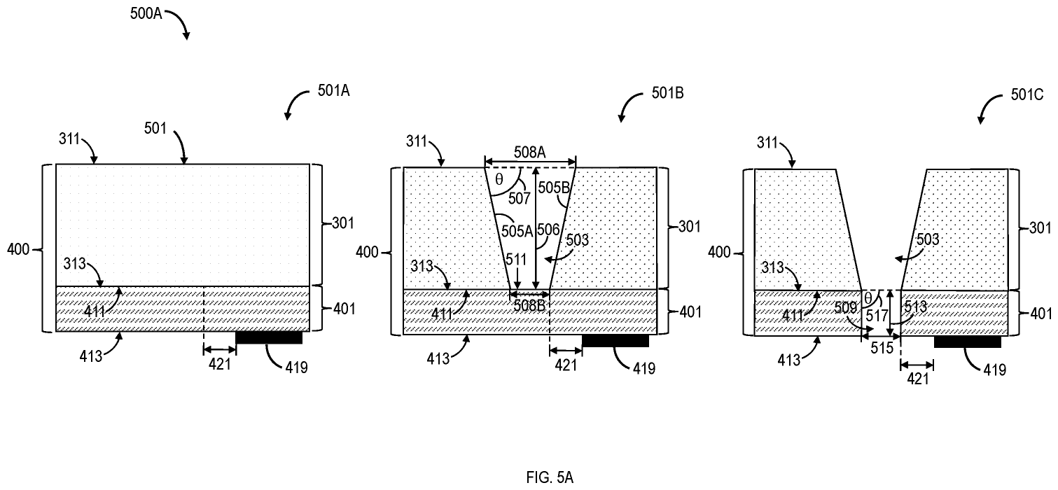

FIG. 5A illustrates generally a cross-sectional view of an example method 500A of generating a feature in a substrate, in accordance with some examples. Method 500 may include operations 501A, 501B and 501C. FIG. 5B illustrates generally a cross-sectional view of an example method 500B of generating a feature in a substrate, in accordance with some examples. Method 500B may include operations 501D, 501E and 501F.

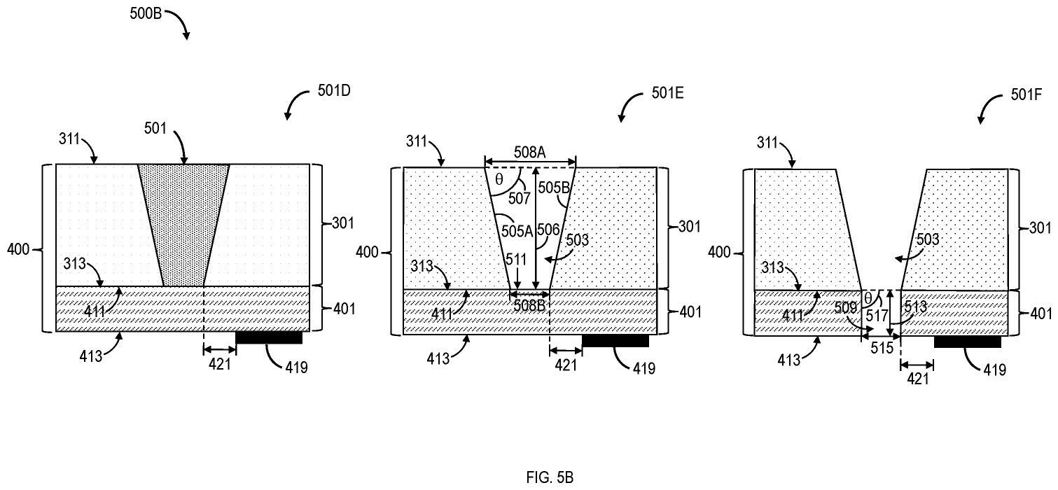

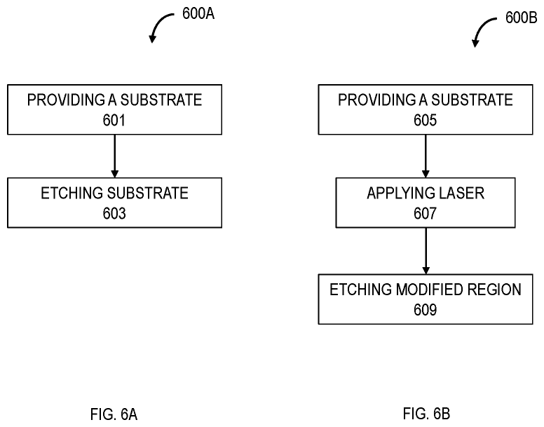

In some examples, FIG. 5A and FIG. 5B illustrate methods of generating a feature in a substrate that has properties or elements similar to those described with respect to structure 400. The feature may comprise properties or elements similar to those described with respect to feature 303 and feature 409. FIG. 6A illustrates generally a flow diagram of an example method 600A of generating a feature in a substrate, in accordance with some examples. Method 600A may include operations 601 and 603. FIG. 6B illustrates generally a flow diagram of an example method 600B of generating a feature in a substrate, in accordance with some examples. Method 600B may include operations 605, 607 and 609. FIG. 7 illustrates generally a flow diagram of an example method 700 of generating a feature in a substrate, in accordance with some examples. Method 700 includes operation 701. In some examples, method 700 may include elements of method 600A or method 600B.

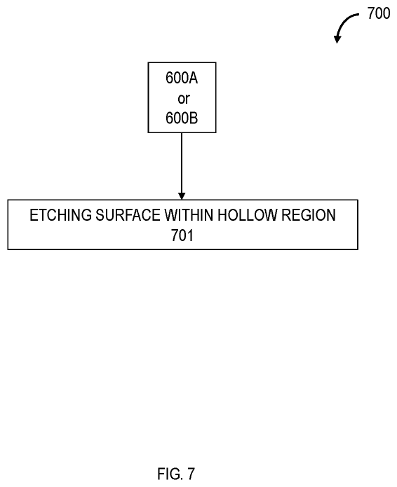

In operation 601, and as illustrated for example in operation 501A, a structure (e.g., structure 400) is provided. The structure 400 may be provided, for example, on a wafer chuck that may hold the wafer in a flat position for processing. In operation 603, and as illustrated for example in operation 501B, at least a portion of the structure 400 is etched. The etching of the structure 400 may include dry etching, such as plasma etching. The plasma etching may include the use of an etch mask (not shown) disposed over a surface (e.g., surface 311) of the structure 400. An example etch mask is described herein with respect to FIG. 8. Plasma etching may include applying a set of selected etching parameters, for example, a plasma power, a bias power and an excitation frequency. The plasma etching of structure 400 may include using a plasma power from about 500 W to about 3000 W. The plasma etching of structure 400 may include using a bias power from about 50 W to about 1000 W. An excitation frequency (e.g., plasma excitation frequency) may be from about 10 MHz to about 50 MHz. The structure 400 may be plasma etched at a rate from about 0.5 microns per minute to about 1.5 microns per minute. An etch selectivity of the etching process of structure 400 may be from about 10:1 to about 50:1.

The etching of the structure 400 may remove at least a portion of the structure 400. The etching of the structure 400 may expose a hollow region 503 within the structure 400. The hollow region 503 may be a region generated within material 301. The hollow region 503 may comprise properties and elements similar to those described with respect to feature 303. The hollow region 503 may be generated in at least a portion of the material 401. The hollow region 503 may comprise sidewalls 505A and 505B. The sidewalls 505A and 505B may comprise properties and elements similar to those described with respect to sidewalls 309A and 309B. The hollow region 503 may comprise an etch angle 507. The etch angle 507 may comprise properties and elements similar to those described with respect to the etch angle 317. The etch angle 507 may comprise an angle measured from a surface (e.g., sidewall 505A) of the hollow region 503 to the horizontal (e.g., horizontal plane located proximate to the surface 311). The etch angle 507 may be greater than or equal to about 80 degrees. The etch angle 507 may be from about 86 degrees to about 90 degrees. The etch angle 507 may be greater than about 90 degrees.

The hollow region 503 may comprise a height (e.g., 506) and a width (or diameter) (e.g., 508A, 508B). The height 506 may be similar to the height of the material 301 or may be a fraction of the height of the material 301 (e.g., less than the height of the material 301). The hollow region 503 may be characterized in part by an aspect ratio. The aspect ratio of the hollow region 503 may be defined by a ratio of the height 506 of the hollow region 503 to the width or diameter (e.g., 508B, 508A). The aspect ratio may be greater than about 1.25:1. The aspect ratio may be greater or equal to about 5:1. The aspect ratio may be from about 1.25:1 to about 11:1. An aspect ratio of the hollow region 503 may be defined by a ratio of a first width or diameter (e.g., 508A) to a second width or diameter (e.g., 508B).

Referring to FIG. 6B, in operation 605, and as illustrated for example in operation 501D, a structure 400 is provided. In operation 607, and as illustrated for example in 501D, a laser is applied to the structure 400. The laser may be applied to a back side of the structure 400. The laser may be applied to an area in which an etching process will follow the laser application. The application of the laser may generate a modified region 501 within the structure 400. The modified region 501 may be generated within material 301 of the structure 400. The modified region 501 may be generated within material 301 of the structure 400. The modified region 501 may comprise a modified crystalline structure of the structure 400. A modified crystalline structure may comprise damage to the crystalline structure. The modified region 501 may comprise a modified crystalline structure of the material 301, the material 401 or both. The laser may be applied at a plurality of focal depths from a surface of the structure 400, for example, from a surface 311 of the material 301. The laser may be a pulsed laser, as described herein. The laser may be applied in accordance with a set of parameters, for example, including average laser power (W), pulse energy (μJ), pulse wavelength (nm), pulse frequency (kHz) and laser scanning speed (mm/s). The laser may be applied to the structure 400 with an average laser power from about 5 W to about 7 W, or another laser power as described herein. The laser may be applied to the structure 400 in accordance with a parameter including a distance between an edge of a component (e.g., component 419) or device and an edge of a modified region to be generated, for example, distance 421.

In operation 609, and as illustrated for example in operation 501E, at least a portion of the modified region 501 is etched. The modified region 501 may be substantially etched. The etching of the modified region 501 removes at least a portion of the modified crystalline structure that is generated by the laser. The modified crystalline structure may be substantially removed. The etching of the modified region 501 may expose a hollow region 503 within the structure 400. The hollow region 503 may be a region generated within material 301. The hollow region 503 may comprise properties and elements similar to those described with respect to feature 303.

The hollow region 503 may comprise sidewalls 505A and 505B. The sidewalls 505A and 505B may comprise properties and elements similar to those described with respect to sidewalls 309A and 309B. The hollow region 503 may comprise an etch angle 507. The etch angle 507 may comprise properties and elements similar to those described with respect to the etch angle 317. The etch angle 507 may comprise an angle measured from a surface (e.g., sidewall 505A) of the hollow region 503 to the horizontal (e.g., horizontal plane located proximate to the surface 311). The etch angle 507 may be greater than or equal to about 80 degrees. The etch angle 507 may be from about 86 degrees to about 90 degrees. The etch angle 507 may be greater than 90 degrees.

The hollow region 503 may comprise a height (e.g., 506) and a width (or diameter) (e.g., 508A, 508B). The height 506 may be similar to the height of the material 301 or may be a fraction of the height of the material 301 (e.g., less than the height of the material 301). The hollow region 503 may be characterized in part by an aspect ratio. The aspect ratio of the hollow region 503 may be defined by a ratio of the height 506 of the hollow region 503 to the width or diameter (e.g., 508B, 508A). The aspect ratio may be greater than about 1.25:1. The aspect ratio may be greater or equal to about 5:1. The aspect ratio may be from about 1.25:1 to about 11:1. An aspect ratio of the hollow region 503 may be defined by a ratio of a first width or diameter (e.g., 508A) to a second width or diameter (e.g., 508B).

The etching of the modified region 501 may include dry etching, such as plasma etching. The plasma etching may include the use of an etch mask (not shown in FIG. 5B) disposed over a surface (e.g., surface 311) of the structure 400. An example etch mask is described herein with respect to FIG. 8. Plasma etching may include applying a set of selected etching parameters, for example, a plasma power, a bias power and an excitation frequency. The plasma etching of structure 400 may include using a plasma power from about 500 W to about 3000 W. The plasma etching of structure 400 may include using a bias power from about 50 W to about 1000 W. An excitation frequency (e.g., plasma excitation frequency) may be from about 10 MHz to about 50 MHz. The structure 400 may be plasma etched at a rate from about 0.5 microns per minute to about 1.5 microns per minute. An etch selectivity of the etching process of structure 400 may be from about 10:1 to about 50:1.

In operation 609, and as illustrated for example in operations 501E and 501F, a surface within the hollow region 503 is etched, for example, surface 511. The surface 511 may be a surface of the material 401. The surface 511 may comprise at least a portion of material 401. The surface 511 may comprise at least a portion of material 301. The etching of the surface 511 may include plasma etching. The etching of the surface 511 may include wet etching or chemical etching. The etching may include the use of an etch mask (not shown) disposed over a surface (e.g., surface 311) of the structure 400. An etch mask used for plasma etching may differ from an etch mask used for wet etching or chemical etching. The etching of the surface 511 may include the removal of at least a portion of the material 401. The etching of the surface 511 may include the removal of at least a portion of material 401 that has been modified by the laser. The etching of the surface 511 may include the removal of at least a portion of the material 301.

As illustrated for example in operation 501F, at least a portion of the material 401 is removed to expose a hollow region 509. The hollow region 509 may comprise properties and elements similar to those described with respect to feature 409. The hollow region 509 may be a region generated within material 401. The hollow region 509 may be generated in at least a portion of the material 301. The hollow region 503 and the hollow region 509 may be coupled. The hollow region 503 and the hollow region 509 may each be at least part of a single hollow region in the structure 400. The hollow region 503 or the hollow region 509, or both, may comprise a feature. The feature may comprise a via through the structure 400. The feature may comprise a channel in the structure 400. The hollow region 503 or the hollow region 509, or both, may be plated with an electrically conductive material. The hollow region 503 and the hollow region 509 may together communicatively couple one location of structure 400 to another location of structure 400, for example, providing current or ground from one location of the structure 400 to a component or device in another location of the structure 400 (e.g., on a surface of the structure 400 or within the structure 400). An edge of a hollow region (e.g., 509, 503 or both) may be disposed a distance 421 from an edge of a component or device (e.g., 419). The component 419 may be a component of a device that is closest to the hollow region.

The hollow region 509 may comprise a height (e.g., 513) and a width or a diameter 515. The height 513 may be similar to the height of the material 401 or may be a fraction of the height of material 401 (e.g., less than the height of material 401). The width or diameter 515 may vary according a location of measurement within the material 401, for example, hollow region 509 may comprise a first width at a location proximate to a first surface 411 of the material 401 and a second width at a location proximate to a second surface 413 of the material 401. Other widths of hollow region 509 may be depending on a location of measurement, for example, depending on a depth within the material 401 relative to a surface (e.g., 411, 413) of the material 401. A width of hollow region 509 may be similar to the width of hollow region 503. The hollow region 509 may comprise a hollow region within the material 401. The hollow region 509 may comprise a hollow region with sidewalls, which may be plated with an electrically conductive material. The hollow region 509 may comprise an etch angle 517. Etch angle 517 may comprise an angle measured from a surface (e.g., sidewall) of the hollow region 509 to the horizontal. The horizontal may be measured from a horizontal plane proximate to the surface 411 of material 401 or surface 113 of material 301. The hollow region 509 may be characterized in part by an aspect ratio. The aspect ratio of the hollow region 509 may be defined by a ratio of the height 513 to the width or diameter 515. An aspect ratio of the hollow region 509 may be defined by a ratio of a first width or diameter (e.g., 515) to a second width or diameter (not shown).

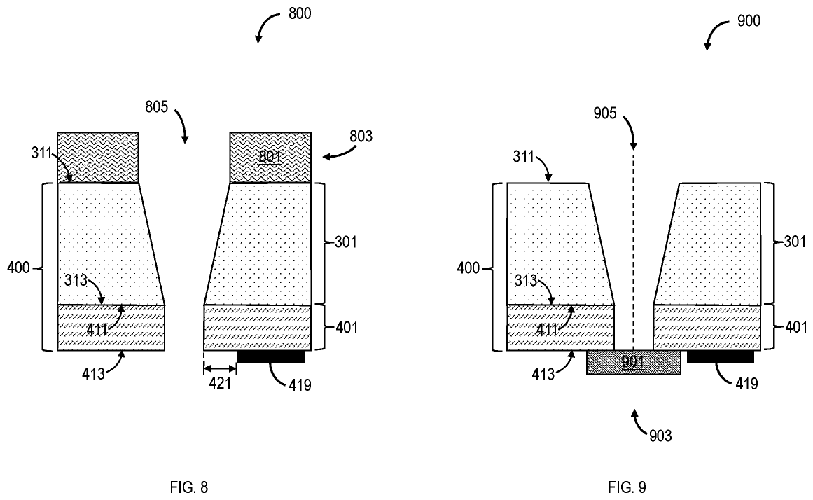

FIG. 8 illustrates generally a cross-sectional view of an example method 800 of generating a feature in a substrate, in accordance with some examples. Method 800 may include operations 803 and 805. FIG. 9 illustrates generally a block diagram of an example method 900 of generating a feature in a substrate, in accordance with some examples. Method 900 may include operations 903 and 905. FIG. 8 and FIG. 9 may illustrate methods of generating a feature in a substrate having properties or elements similar to those described with respect to structure 400. The feature may comprise properties or elements similar to those described with respect to feature 303, feature 409, hollow region 303, hollow region 409 or hollow region 509. The method 800 may include elements of method 500A or 500B. The method 900 may include elements of method 500A or 500B.

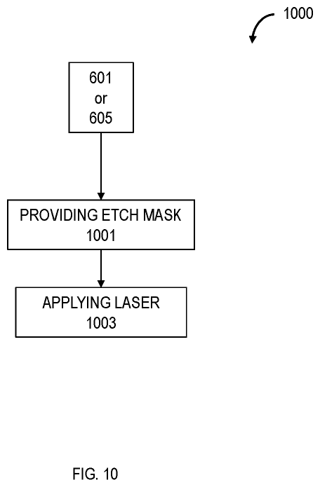

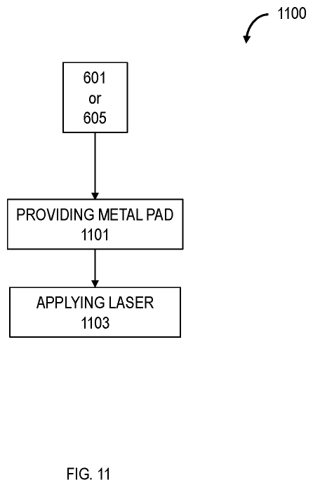

FIG. 10 illustrates generally a flow diagram of an example method 1000 of generating a feature in a substrate, in accordance with some examples. Method 1000 may include operations 1001 and 1003. Method 1000 may include elements of method 600A or 600B. FIG. 11 illustrates generally a flow diagram of an example method 1100 of generating a feature in a substrate, in accordance with some examples. Method 1100 includes operations 1101 and 1103. Method 1100 may include elements of method 600A or 600B.

In method 800, a substrate (e.g., structure 400) is provided. The structure 400 may comprise an etch mask (e.g., 801). In operation 1001, and as illustrated for example in operation 803, an etch mask 801 is provided. The etch mask 801 may be an etch mask as described herein and may be an etch mask for dry etching (e.g., plasma etching) or for wet etching or chemical etching. The etch mask 801 may be provided in method 500A, method 500B, method 800 or method 900. Operation 1001 may comprise applying the etch mask 801 to the structure 400. The etch mask 801 may be applied prior to application of a laser and etching process. In operation 1003, and as illustrated for example in operation 805, a laser is applied to the structure 400 to generate a modified region (e.g., similar to 501 in FIG. 5B) with the etch mask 801 in place. For simplicity, FIG. 8 does not illustrate a modified region in structure 400 and instead illustrates a hollow region or a feature, which may be similar to the hollow regions or features in FIG. 3 through FIG. 5B. The etch mask 801 is applied to the structure 400 to generate a selected distance (e.g., 421) between an edge of a device or component (e.g., 419) and an edge of a feature to be generated. The laser may be applied in a region within an opening of the etch mask 801.

In method 900, a substrate (e.g., structure 400) is provided. The structure 400 may comprise an etch mask (e.g., 801). The structure 400 may comprise a metal pad (e.g., 901). In operation 1101, and as illustrated for example in operation 903, a metal pad 901 is provided. The metal pad 901 may be provided as part of the structure 400, prior to a laser process. The metal pad may be a metal via pad for communicatively coupling a via or an interconnect to a location of the structure 400 or to a device or component (e.g., 419) disposed on or within the structure 400. For example, the metal via pad may be a ground for a terminal of a device such as a transistor. In operation 1103, and as illustrated for example in operation 905, a laser is applied to the structure 400 to generate a modified region (e.g., similar to 501 in FIG. 5B) with the metal pad 901 in place. For simplicity, FIG. 9 does not illustrate a modified region in structure 400 and instead illustrates a hollow region or a feature, which may be similar to the hollow regions or features in FIG. 3 through FIG. 5B. The laser may be applied to the structure 400 such that a modified region to be generated in the structure 400 overlaps the metal pad 901, at least in part or substantially.

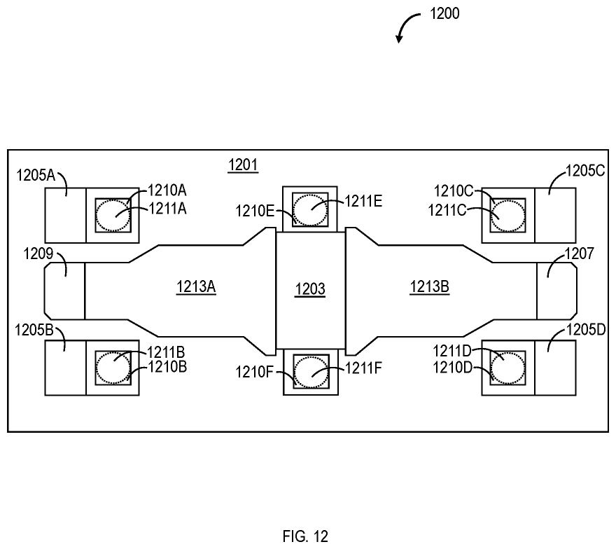

FIG. 12 illustrates generally a block diagram of an example device 1200, in accordance with some examples. FIG. 12 may illustrate a top-down view of a block diagram of the example device 1200, for example, illustrating a front side of the example device 1200. The device 1200 may comprise a structure 1201, which may comprise a substrate. The structure 1201 may comprise one or more materials as described herein. For example, the structure 1201 may comprise a material having a thermal conductivity of at least about 1,000 W/mK in at least a single dimension. The substrate material may be a carbon-based material, for example, diamond. The structure 1201 may also comprise one or more other materials, for example, a semiconductor-containing material as described herein (e.g., wide-bandgap semiconductor material). The substrate 1001 may include one or more intermediate layers.

The device 1200 may comprise a transistor. A transistor may include, for example, a field effect transistor (FET), such as a high electron mobility transistor (HEMT). The transistor may include a Metal-Insulator-Semiconductor Field Effect Transistors (MISFET). Other devices may include bipolar transistors, Schottky diodes, switching diodes, and mixing diodes, microwave diodes, semiconductor lasers, light-emitting diodes and super-luminescent diodes. The device 1200 may comprise a power amplifier. The device 1200 may comprise an integrated circuit, such as a MMIC.

The device 1200 may comprise one or more features, such as one or more interconnects or vias (e.g., 1211A through 1211F). A feature may be as described herein. For example, any one or more of vias 1211A through 1211F may be round, rectangular or other shaped vias and may have characteristics including aspect ratios and etch angles as described herein. The one or more vias may be generated in the device 1200 in accordance with the methods described herein. A via may be generated in part according to a selected distance from one or more of the components of device 1200, such as an active region 1203. The one or more vias may be generated in the device 1200 while causing minimal or no damage to the components of the device 1200.

The device 1200 may comprise the active region 1203, comprising a layout of one or more transistors. The layout may comprise the one or more transistors arranged in parallel. A transistor may comprise a source region, a drain region and a gate region. A transistor region may be communicatively coupled to a terminal or a metal pad. The active region 1203 may comprise one or more drain pads and one or more source pads. A gate may comprise a gate finger. The device 1200 may comprise one or more metal pads, for example, one or more source metal pads (e.g., 1205A through 1205D), one or more drain metal pads (e.g., 1207) and one or more gate metal pads (e.g., 1209). A metal pad may communicatively couple to a device terminal and interconnect, or both. A metal pad may be used to communicatively couple a terminal to an applied voltage. The device 1200 may comprise one or more frontside metal pads (e.g., 1210A through 1210F). The frontside metal pads may be used for communicatively coupling the front side of the device 1200 (e.g., front side) to a feature, such as a via.

A feature (e.g., via) may communicatively couple one location of the device to another (e.g., the front side of the device 1200 to the back side of the device 1200), for example, coupling a terminal on a front side of the device 1200 to ground on the back side of the device 1200. The back side of the device 1200 may comprise metal (not shown). The metal on the back side of the device 1200 may communicatively couple the active region 1203 to the frontside vias (e.g., 1211A through 1211F). The metal pads may be metal pads for interconnects, such as vias. A source metal pad, for example, may be used to communicatively couple a source terminal of the device 1200 to ground. The device 1200 may comprise interconnects 1213A and 1213B. The interconnects 1213A and 1213B may be metal interconnects that communicatively couple the active region 1203 to metal pads (e.g., gate metal pad 1209 and drain metal pad 1207). The interconnects 1213A and 1213B may be, for example, microstrip interconnects.

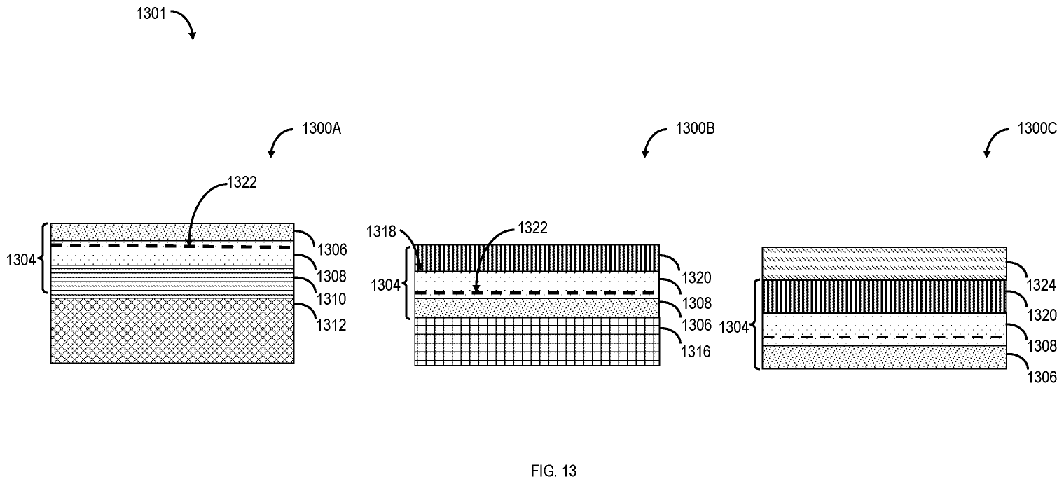

FIG. 13 illustrates generally a cross-sectional view of an example method of forming a structure 1301, in accordance with some examples. The structure 1301 may comprise a substrate. The structure 1301 may comprise a device as described herein. The method may comprise operations 1300A, 1300B and 1300C. As illustrated in operation 1300A, of the method of forming a device may comprise generating a layered structure 1304 on a substrate 1312. The substrate 1312 may be a first temporary substrate. The substrate may comprise silicon, bulk GaN, bulk SiC, or any type of substrate as disclosed herein. The layered structure 1304 may comprise a plurality of epitaxial layers. The layered structure 1304 may comprise wide-bandgap semiconductor layers. The layered structure 1304 may comprise a III-V semiconductor. The layered structure 1304 may comprise a III-III′-V semiconductor. The layered structure 1304 may comprise a buffer layer 1308 and a barrier layer 1306, which may be adjacent to one another and which may form a heterostructure. The buffer layer 1308 may be grown adjacent to an intermediate layer 1310 (e.g., transition layer(s)), which may be adjacent to the substrate 1312. The intermediate layer 1310 may comprise AlGaN. The intermediate layer 1310 may aid in growth of the layered structure 1304, such as the buffer layer 1308. The buffer layer 1308 may comprise a semiconductor comprising an element from Group III and an element from Group V. The barrier layer 1306 may comprise at least one layer of a material comprising scandium, a second element from Group III, and an element from Group V. The buffer layer 1308 may comprise GaN. The barrier layer 1306 may comprise ScAlN (e.g., ScₓAl₁₋ₓN alloy).

As illustrated in Operation 1300B, the method of forming the device may comprise flipping the layered structure 1304 and attaching the layered structure 1304 to a second temporary substrate 1316 (e.g., carrier wafer or handle) such that the barrier layer 1306 is disposed adjacent to the second temporary substrate 1316. Operation 1300B may comprise removing the substrate 1312 and the intermediate layer 1310 shown in FIG. 13A to expose a surface of the buffer layer 1308 at surface 1318. A portion of the buffer layer 1308 may also be removed (e.g., during the removal of the intermediate layer 1310). Operation 1300B may comprise generating an additional intermediate layer 1320 disposed adjacent to the buffer layer 1308. The layered structure 1304 may include the additional intermediate layer 1320. The intermediate layer 1320 may be provided having sufficient thickness to nucleate diamond growth. The thickness of an intermediate layer 1320 may be less than about 150 nm, or other thicknesses as described herein. The buffer layer 1308 may be thinned to customize a distance between a 2DEG layer (e.g., 1322), proximate to the heterojunction between the buffer layer 1308 and the barrier layer 1306, and a high-thermal conductivity substrate 1324 to be generated (e.g., as illustrated in Operation 1300C). The buffer layer 1308 may be thinned by an etching process as described herein.

The distance between a 2DEG layer 1322 and the high-thermal conductivity substrate 1324 may be equal to or less than about 1 micron (e.g., equal to or less than 750 nm) or another distance as described herein. Adjusting a thickness of the buffer layer 1308 may help to control an average value of thermal conductivity of the device. Reducing the thickness of a buffer layer 1308 may comprise controlling the thickness of the buffer layer 1308. Reducing the thickness of the buffer layer 1308 may improve thermal management of the device. In some cases, such as when the buffer layer 1308 is deposited at an appropriate thickness, the buffer layer 1308 may not be thinned.

As illustrated in Operation 1300C, the method of forming the device may comprise generating a layer of a high-thermal conductivity substrate 1324 adjacent to the intermediate layer 1320. The substrate 1324 may be a carbon-containing substrate, such as diamond, synthetic diamond, or other high-thermal conductivity materials as described herein. The growth direction of a material of the substrate 1324 may be the same as the growth direction of the layered structure 1304. The thickness of the substrate 1324 may vary from approximately several micrometers to hundreds of micrometers or up to millimeters. The substrate 1324 may serve as a substrate for a device as described herein. Operation 1300C may include removing the second temporary substrate 1316 shown in Operation 1300B. Operation 1300C may include generating one or more additional semiconductor layers disposed adjacent to the layered structure 1304. The layered structure 1304 may include the high-thermal conductivity substrate 1324. The layered structure 1304 may be flipped and additional operations may be performed on a surface of the layered structure 1304, including the formation of one or more devices or substrate features as described herein.

The method may further comprise generating one or more contacts disposed on the layered structure 1304. Such contacts may comprise a source contact, a drain contact, and a gate contact. The one or more contacts may allow for electrical control of a device as described herein. A voltage may be applied to the gate contact. A voltage and/or a current may be measured off of the source contact. A voltage and/or a current may be measured off of the drain contact. One or more of the contacts may be in electrical connection with other components or elements as described herein (e.g., transistors). An electric field may be used to control the flow of current between two contacts or terminals in the device such as a source contact and a drain contact.

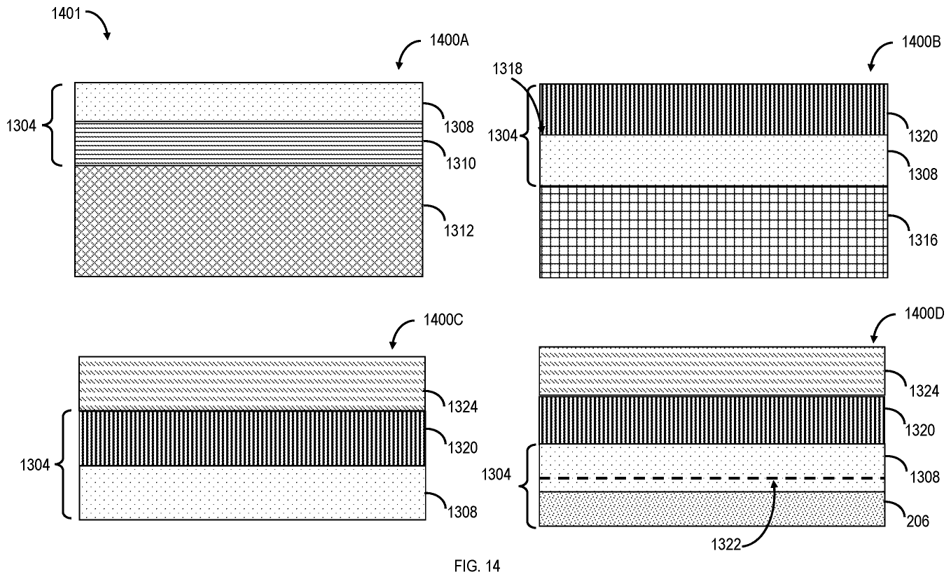

FIG. 14 illustrates generally a cross-sectional view of an example method of forming a structure 1401, in accordance with some examples. The structure 1401 may comprise a substrate. The structure 1401 may comprise a device as described herein. The method may comprise operations 1400A, 1400B, 1400C and 1400D. The structure 1401 may comprise one or more elements similar to the elements of structure 1301.

As illustrated in FIG. 14, Operation 1400A may comprise providing a layered structure 1304. The layered structure 1304 may be grown or disposed on a substrate 1312. Some examples include generating the layered structure 1304 on the substrate 1312. The substrate 1312 may be a first temporary substrate. The substrate may comprise silicon, bulk GaN, bulk SiC, or any type of substrate as disclosed herein. The layered structure 1304 may comprise a plurality of epitaxial layers. The layered structure 1304 may comprise wide-bandgap semiconductor layers. The layered structure 1304 may comprise a III-V semiconductor. The layered structure 1304 may comprise a III-III′-V semiconductor. The layered structure 1304 may comprise a buffer layer 1308. The buffer layer 1308 may be grown adjacent to an intermediate layer 1310, which may be adjacent to the substrate 1312. The buffer layer 1308 may comprise GaN. The intermediate layer 1310 may comprise AlGaN. The intermediate layer 1310 may aid in growth of the layered structure 1304, such as the buffer layer 1308.

Operation 1400B may comprise providing flipping the layered structure 1304 and attaching the layered structure 1304 to a second temporary substrate 1316 (e.g., carrier wafer or handle) such that the buffer layer 1308 is disposed adjacent to the second temporary substrate 1316. Operation 1400B may comprise removing the substrate 1312 and the intermediate layer 1310 to expose a surface of the buffer layer 1308 at surface 1318.

A portion of the buffer layer 1308 may also be removed (e.g., during the removal of the intermediate layer 1310). Operation 1400B may comprise generating an additional intermediate layer 1320 disposed adjacent to the buffer layer 1308. The layered structure 1304 may include the additional intermediate layer 1320. The additional intermediate layer 1320 may be provided having sufficient thickness to nucleate diamond growth. The thickness of the additional intermediate layer 1320 may be less than about 150 nm, or another thickness as described herein. The buffer layer 1308 may be thinned to customize a distance between a 2DEG layer (e.g., 1322) to be generated proximate to an interface to be generated between the barrier layer 1306 and the buffer layer 1308, and a high-thermal conductivity substrate 1324. The distance between a 2DEG layer 1322 and the high-thermal conductivity substrate 1324 may be less than or equal to about 750 nm or another distance as described herein. Adjusting a thickness of a buffer layer 1308 may help to control a thermal conductivity of the device. Reducing the thickness of a buffer layer 1308 may comprise controlling the thickness of the buffer layer 1308 (e.g., during formation of the buffer layer 1308). Reducing the thickness of the buffer layer 1308 may improve thermal management of the device. In some cases, such as when the buffer layer 1308 is deposited at an appropriate thickness, the buffer layer 1308 may not be thinned.

Operation 1400C may comprise generating a layer of a high-thermal conductivity substrate 1324 adjacent to the intermediate layer 1320. The substrate 1324 may be a carbon-containing substrate, such as diamond, synthetic diamond, or other high-thermal conductivity materials as described herein. The growth direction of a material of substrate 1324 may be the same as the growth direction of the layered structure 1304. The thickness of the substrate 1324 may vary from approximately several micrometers to hundreds of micrometers or up to millimeters. The substrate 1324 may serve as a substrate for a device as described herein. Operation 1400C may include removing the second temporary substrate 1316. Operation 1400C may include generating one or more additional semiconductor layers disposed adjacent to the layered structure 1304. The layered structure 1304 may include the high-thermal conductivity substrate 1324.

Operation 1400D may comprise generating a barrier layer 1306 disposed adjacent to the buffer layer 1308. The barrier layer 1306 and the buffer layer 1308 may form a heterojunction at the interface between the barrier layer 1306 and the buffer layer 1308. The barrier layer 1306 may be part of the layered structure 1304. Operation 1400D may comprise generating one or more additional semiconductor layers disposed adjacent to the layered structure 1304. Operation 1400D may comprise generating one or more contacts disposed on the layered structure 1304. Such contacts may comprise a source contact, a drain contact, and a gate contact. The one or more contacts may allow for electrical control of a device as described herein. A voltage may be applied to the gate contact. A voltage and/or a current may be measured off of the source contact. A voltage and/or a current may be measured off of the drain contact. One or more of the contacts may be in electrical connection with other elements, such as other transistors. An electric field may be used to control the flow of current between two contacts or terminals in the device such as a source contact and a drain contact. While FIG. 13 and FIG. 14 illustrate methods of forming devices in accordance with embodiments, a person of ordinary skill in the art will recognize many adaptations and variations may be contemplated. Further, one or more steps shown in FIG. 13 and FIG. 14 may be deleted or repeated, additional steps may be added, and the steps may be performed in any order.

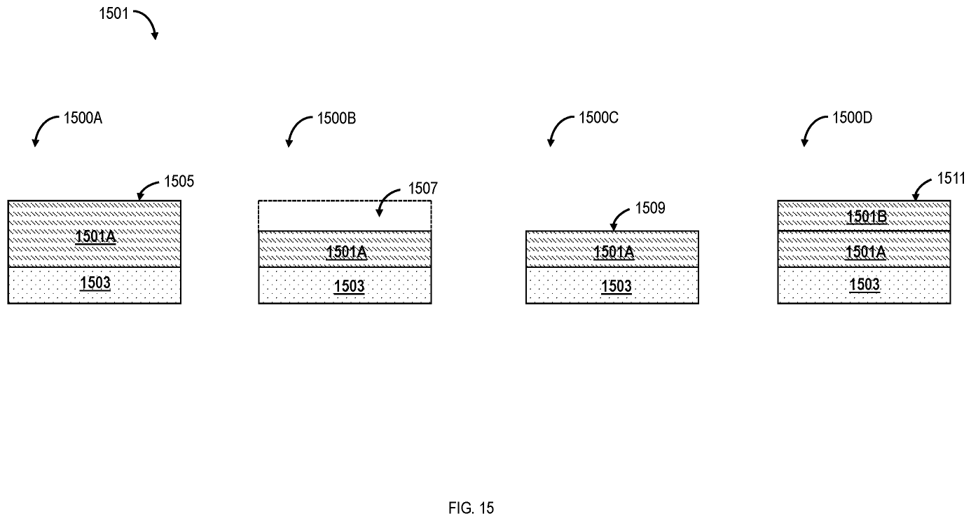

FIG. 15 illustrates generally a flow of an example method of forming a structure 1501, in accordance with some examples. The structure 1501 may comprise a substrate. The structure 1501 may comprise a device as described herein. Structure 1501 may comprise one or more properties or elements similar to those described with respect to structure 100, 200, 300, 400, 1201, 1301 or 1401.

In operation 1500A, a substrate is provided. The substrate may comprise a semiconductor-containing layered structure. The semiconductor-containing layered structure may comprise substrate 1503 and material 1501A. The substrate 1503 may be a thermally conductive substrate, as described herein. The substrate 1503 may comprise a material having an average value of thermal conductivity equal to or greater than about 1,000 W/mK. The substrate 1503 may comprise diamond. The material 1501A may be a semiconductor-containing material. The material 1501A may comprise a wide-bandgap semiconductor material. The material 1501A may comprise a material including one or more of GaN, AlN, InGaN, InAlN, AlGaN, InGaAlN, Ga2O3, ScAlN, and derivatives and combinations of thereof. The material 1501A may comprise substantially GaN.

In some examples, where the material 1501A comprises GaN, a surface of the material 1501A may comprise an N-faced surface 1505. The N-faced surface 1505, and a region proximate to the N-faced surface 1505, may comprise a higher density of nitrogen atoms than another region of the material 1501A, for example, a region of the material 1501A proximate to an interface between the material 1501A and the substrate 1503.

In operation 1500B, a portion 1507 of the material 1501A may be removed. Removal of the portion 1507 may comprise etching the material 101A. Etching may comprise wet etching (e.g., chemical etching) or dry etching (e.g., plasma etching). Removal of the portion 1507 may comprise grinding or other methods or removal. The portion 1507 may comprise an average height or an average thickness. An average height or thickness may be less than or equal to about 500 Angstroms, greater than about 500 Angstroms, within a range from about 500 Angstroms to about 1 micron, less than or equal to about 1 micron, about 0.5 microns, about 0.25 microns, or other thicknesses or heights, for example.

In some examples, the portion 1507 of the material 1501A may comprise modified crystalline structures of the material 1501A. The modified crystalline structures of the material 1501A may comprise at least a portion of a surface of the material 1501A, for example, surface 1505. The portion 1507 may comprise a surface (e.g., surface 1505) of the material 1501A. The crystalline structures of the material 1501A of the portion 1507 may be modified during a process of manufacturing the substrate. For example, processes of manufacturing may include subjecting the substrate to temperatures in excess of a threshold temperature. Processes may also include exposing the substrate to such temperatures for periods of time in excess of a threshold time period. Exposure to such processes, in part, may generate modifications to the crystalline structures on a surface of the material 1501A.

In some examples, the material 1501A may have an average thickness after removal of the portion 1509. An average thickness of the material 1501A after removal of the portion 1507 may be equal to or greater than about 0.1 microns, 0.2 microns, or 0.3 microns, for examples, An average thickness of the material 1501A after removal of the portion 1507 may be within a range from about 0.1 microns to about 0.2 microns, from about 0.2 microns to about 0.3 microns, from about 0.3 microns to about 0.4 microns, from about 0.4 microns to about 0.5 microns, from about 0.5 microns to about 0.6 microns, or greater. In such examples, a thickness of a nucleation layer of the substrate (if the substrate comprises a nucleation layer or nucleation material) or an adhesion layer (for adhering the material 1501A to the substrate 1503) may be modified in accordance with a thickness of the material 1501A. In some examples, if a nucleation layer or an adhesion layer has a thickness of about 0.25 microns, the material 1501A may have a thickness of about 0.75 microns. A nucleation layer or adhesion layer may have a thickness equal to or less than 10 nm.

In operation 1500C, the material 1501A may be cleaned. For example, a surface 1509 of the material 1501A may be cleaned. The surface 1509 may be cleaned after the portion 1507 is removed. Cleaning the surface may remove organic material or metals, or both. In some examples, the surface 1509 is cleaned prior to a regrowth process. The surface 1509 may be cleaned by providing the substrate in a chamber. Cleaning the surface 1509 may include etching.

The substrate may be provided by placing the substrate in a chamber. A chamber may be a reaction chamber or a growth chamber, for example. A chamber may be a molecular beam epitaxy (MBE) chamber. A chamber may be a chamber used for chemical vapor deposition (CVD). A chamber may be a chamber used for low pressure chemical vapor deposition (LPCVD). A chamber may be a metal organic chemical vapor deposition (MOCVD) chamber.

In operation 1500D, material 1501B is generated over a surface of the material 1501A. The material 1501B may be a semiconductor-containing material. The material 1501B may comprise a wide-bandgap semiconductor material. The material 1501B may comprise a material including one or more of GaN, AlN, InGaN, InAlN, AlGaN, InGaAlN, Ga2O3, ScAlN, and derivatives and combinations of thereof. The material 1501B may comprise substantially GaN. The material 1501B may comprise substantially SiN. The material 1501A and the material 1501B may comprise substantially the same material. The material 1501A and material 1501B may comprise substantially GaN. The material 1501B may be a regrowth layer, as described herein.

The material 1501B may comprise an average height or an average thickness. An average height or thickness may be less than or equal to about 500 Angstroms, greater than about 500 Angstroms, within a range from about 500 Angstroms to about 1 micron, less than or equal to about 1 micron, about 0.5 microns, about 0.25 microns, or other thicknesses or heights, for example. The height or thickness of the material 1501B may be substantially similar to the height or thickness of the portion 1507 removed from the material 1501A. The material 1501B may be generated in accordance with a set of parameters. The set of parameters may define one or more gases to be introduced into the chamber, one or more temperature values, and one or more time period values. The set of parameters may define a period of time over which the substrate may be heated. The set of parameters may define a period of time over which the substrate may be cooled. The set of parameters may define operating conditions in a chamber, such as temperature (° C.), pressure (Pa), and gas flow rate (standard cubic centimeters per minute (SCCM)).

A set of parameters may be selected in accordance with one or more properties of the substrate, for example, a surface property. A surface property may include a surface leakage current. A set of parameters may be selected in accordance with a threshold value for a surface leakage current of a surface to be generated on the substrate (e.g., surface 1511). Operation 1500D may comprise generating the material 1501B in accordance with a surface property of a surface of the material 1501B to be generated.

A set of parameters for generating the material 1501B may be selected in accordance with a surface leakage current less than about 10⁻⁷ A at 10 V as measured by capacitance-voltage (C-V) testing. A set of parameters for generating the material 1501B may be selected in accordance with a surface leakage current less than about 10⁻⁵ A, less than 10⁻⁷ A, less than 10⁻⁸ A, less than 10⁻¹⁰ A, or less, within a range from about 10⁻⁵ A to about 10⁻⁷ A, within a range from about 10⁻⁷ A to about 10⁻¹⁰ A, within a range from about 10⁻¹⁰ A to about 10⁻¹² A, or less. C-V testing may be performed using two electrical contacts. Two electrical contacts may comprise a mercury (Hg) probe tool with a mercury center dot. A mercury center dot may be about 760 microns in diameter. C-V testing may be performed by applying a voltage between the two contacts. Such voltage may be about 10 V, greater than about 10 V, or greater. An observed current using the applied voltage may indicate a surface leakage current of a surface of the substrate (e.g., surface 1511).

Generating the material 1501B may comprise heating the substrate to a threshold temperature. Some examples include heating the substrate to a temperature in excess of the threshold temperature for a period of time. A threshold temperature may be equal to or greater than about 700 degrees C. A threshold temperature may be a temperature within a range from about 700 degrees C. to about 800 degrees C., from about 800 degrees C. to about 900 degrees C., from about 900 degrees C. to about 1,000 degrees C., from about 1,000 degrees C. to about 1,050 degrees C., from about 1,050 degrees C. to about 1,100 degrees C., or greater. A period of time for generating the material 1501B may be, for example, about 10 minutes. A period of time may be within a range from about 10 minutes to about 25 minutes, from about 25 minutes to about 45 minutes, from about 45 minutes to about 1 hour, or greater. A period of time for generating the material 1501B may be selected based on one or more properties of the material 1501A. A period of time for generating the material 1501B may be selected based on the type of chamber used or other methods of generating the material 1501B.

Operation 1500D may comprise introducing a flow of one or more gases into the chamber to generate material 1501B. Generating material 1501B may comprise depositing a layer of material 1501B onto a surface (e.g., 1509) of the material 1501A. A flow of gases introduced into the chamber may comprise one or more of Tri-methyl Gallium, Tri-methyl Aluminum or nitrogen (e.g., background nitrogen). The material 1501B may be deposited such that at least a portion of the material 1501B is in contact with the material 1501A. In some examples, an interface between the material 1501A and the material 1501B may exhibit a carbon peak that is greater than an average carbon background of the substrate (e.g., material 1501A, material 1501B) as measured by SIMS. In some examples, a carbon peak at an interface between the material 1501A and the material 1501B may exhibit a carbon peak at least about 1.5 times greater than an average carbon background of the substrate (e.g., material 1501A, material 1501B). The material 1501B and material 1501A may form a buffer layer of the substrate. In some examples, one or more devices may be formed over a surface (e.g., 1511) of the material 101B. Such devices may include transistors, as described herein.

Operation 1500D may include generating a 2DEG (e.g., 2DEG layer, 2DEG source, 2DEG channel) in the material 1501B or over a surface of the material 1501B (not shown in FIG. 15). A device, such as a transistor, formed on the substrate may operate in part by current flowing in the 2DEG. Current may flow in the 2DEG layer when a voltage is applied between two terminals of the device (e.g., gate terminal and source terminal). A 2DEG layer may be disposed between a buffer layer (e.g., the material 1501A and the material 1501B) and a barrier layer (not shown in FIG. 15). A 2DEG may be formed in part by depositing one or more semiconductor-containing materials, for example, AlGaN. A width of the 2DEG layer may be less than 50 nm, less than 10 nm, or less than 5 nm. In some cases, the 2DEG layer may be no further than 150 nm from an edge of the substrate 1503. In some cases, the 2DEG layer may be no further than 250 nanometers from an edge of the substrate 1503, no further than 500 nm from an edge of the substrate 1503, no further than 750 nm from an edge of the substrate 1503, no further than 1 micron from an edge of the substrate 1503, or no further than 100 microns from an edge of the substrate 1503.

Some examples include generating a barrier layer over a surface of the material 1501B. A barrier layer may comprise materials as described herein. The barrier layer may be generated in a chamber, as described herein. One or more devices may be generated on a surface of the substrate in a chamber as described herein. Operation 1500D may further comprise generating an additional layer of a semiconductor-containing material over a surface (e.g., 1511) of the material 1501B.

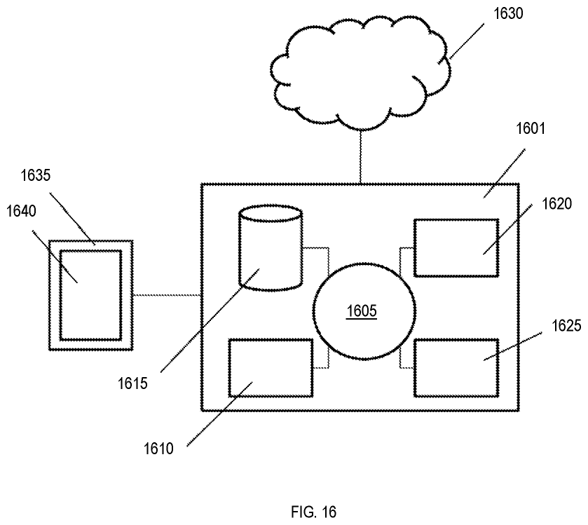

The present disclosure provides examples of computer systems that can be programmed to implement methods of the disclosure, such as methods for generating features in substrates, as disclosed herein. FIG. 16 illustrates a computer system 1601 that can be programmed or otherwise configured to form an example device, in accordance with some examples. The computer system 1601 may be used to control one or more tools that can be used for forming a layered structure. The tools may include, for example a deposition chamber, an etching chamber, lithography equipment, chemical baths, cleaning chambers, and any other equipment associated with semiconductor, wafer level, or thin film processing.

The computer system 1601 includes a central processing unit (CPU, also “processor” and “computer processor” herein) 1605, which can be a single core or multi core processor, or a plurality of processors for parallel processing. The computer system 1601 also includes memory or memory location 1610 (e.g., random-access memory, read-only memory, flash memory), electronic storage unit 1615 (e.g., hard disk), communication interface 1620 (e.g., network adapter) for communicating with one or more other systems, and peripheral devices 1625, such as cache, other memory, data storage and/or electronic display adapters. The memory 1610, storage unit 1615, interface 1620 and peripheral devices 1625 are in communication with the CPU 1605 through a communication bus (solid lines), such as a motherboard. The storage unit 1615 can be a data storage unit (or data repository) for storing data. The computer system 1601 can be operatively coupled to a computer network (“network”) 1630 with the aid of the communication interface 1620. The network 1630 can be the Internet, an internet and/or extranet, or an intranet and/or extranet that is in communication with the Internet. The network 1630 in some cases is a telecommunication and/or data network. The network 1630 can include one or more computer servers, which can enable distributed computing, such as cloud computing. The network 1630, in some cases with the aid of the computer system 1601, can implement a peer-to-peer network, which may enable devices coupled to the computer system 1601 to behave as a client or a server. The CPU 1605 can execute a sequence of machine-readable instructions, which can be embodied in a program or software. The instructions may be stored in a memory location, such as the memory 1610. The instructions can be directed to the CPU 1605, which can subsequently program or otherwise configure the CPU 1605 to implement methods of the present disclosure. Examples of operations performed by the CPU 1605 can include fetch, decode, execute, and writeback.

The CPU 1605 can be part of a circuit, such as an integrated circuit. One or more other components of the system 1601 can be included in the circuit. In some cases, the circuit is an application specific integrated circuit (ASIC). The storage unit 1615 can store files, such as drivers, libraries and saved programs. The storage unit 1615 can store user data, e.g., user preferences and user programs. The computer system 1601 in some cases can include one or more additional data storage units that are external to the computer system 1601, such as located on a remote server that is in communication with the computer system 1601 through an intranet or the Internet. The computer system 1601 can communicate with one or more remote computer systems through the network 1630. For instance, the computer system 1601 can communicate with a remote computer system of a user. Examples of remote computer systems include personal computers (e.g., portable PC), slate or tablet PC's (e.g., Apple® iPad, Samsung@Galaxy Tab), telephones, Smart phones (e.g., Apple® iPhone, Android-enabled device, Blackberry®), or personal digital assistants. The user can access the computer system 1601 via the network 1630. Methods as described herein can be implemented by way of machine (e.g., computer processor) executable code stored on an electronic storage location of the computer system 1601, such as, for example, on the memory 1610 or electronic storage unit 1615. The machine executable or machine-readable code can be provided in the form of software. During use, the code can be executed by the processor 1605. In some cases, the code can be retrieved from the storage unit 1615 and stored on the memory 1610 for ready access by the processor 1605. In some situations, the electronic storage unit 1615 can be precluded, and machine-executable instructions are stored on memory 1610.

The code can be pre-compiled and configured for use with a machine having a processer adapted to execute the code or can be compiled during runtime. The code can be supplied in a programming language that can be selected to enable the code to execute in a pre-compiled or as-compiled fashion. Examples of the systems and methods provided herein, such as the computer system 1601, can be embodied in programming. Various examples of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, etc. shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution. The computer system 1601 can include or be in communication with an electronic display 1635 that comprises a user interface (UI) 1640. Examples of UI's include, without limitation, a graphical user interface (GUI) and web-based user interface. Methods and systems of the present disclosure can be implemented by way of one or more algorithms. An algorithm can be implemented by way of software upon execution by the central processing unit 1605.

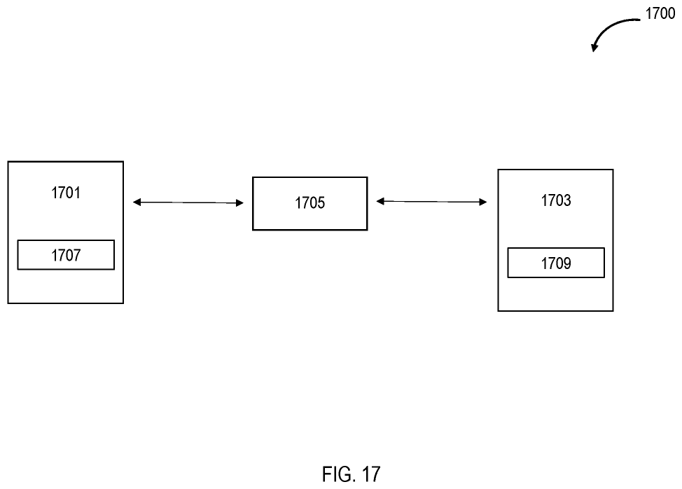

FIG. 17 illustrates a block diagram of an example system 1700 including one or more devices that comprise a semiconductor-containing substrate, in accordance with some embodiments disclosed herein. System 1700 may be a wireless system, for example, a wireless communication system (e.g., radio-frequency (RF), microwave, free-space optical) or a wireless power transfer system. System 1700 includes device 1701, device 1703 and link 1705. Device 1701 and device 1703 may be configured to communicate wirelessly over link 1705. Link 1705 may comprise wireless communications (e.g., electromagnetic signals) between device 1701 and device 1703 and may be characterized by parameters including path loss. In examples where system 1700 is not a wireless system, link 1705 may be a cable (e.g., electrical conductor or optical fibers). Device 1701, device 1703, or both may include circuitry or components comprising substrates similar to substrate 105, substrate 203, substrate 1312, substrate 1314, substrate 1503, or other substrates manufactured according to the methods described herein. By comprising such substrates, devices 1701 and 1703 may provide improvements in wireless communications through, at least, improved device thermal efficiencies and power-added efficiencies (PAE).

Device 1701 may include a transmitter 1707 for transmitting electromagnetic signals to device 1703. Device 1703 may include a receiver 1709 for receiving electromagnetic signals from device 1701. Transmitter 1707 may be an RF or microwave transmitter, including transmitting circuitry configured to be communicatively coupled to one or more antennas, for transmitting RF or microwave signals over link 1705 to device 1703. In some examples, transmitter 1707 may be an optical transmitter, communicatively coupled to optical transmitting circuitry and components, for transmitting optical signals over link 1705 to device 1703. Receiver 1709 may be an RF or microwave receiver, including receiving circuitry configured to be communicatively coupled to one or more antennas, for receiving RF or microwave signals over link 1705 from device 1701. Device 1701 and device 1703 may also include circuitry configured for both transmitting and receiving functions (e.g., transceiver).

Device 1701 and device 1703 may also include components such as processor(s), memory, input device(s), output controller(s), signal generation device(s), network interface device(s), sensor(s), and power source(s), which some or all may communicate with each other via an interlink (e.g., bus). Device 1701 and device 1703 may be terrestrial or aerial devices, and may be stationary or mobile. Nonlimiting examples of stationary devices include, for example, land stations (e.g, base station, node, access point) or ground stations (e.g., earth station, terminal, gateway). Nonlimiting examples of mobile devices include, for example, vehicular devices, aerial devices or mobile client devices. Device 1701 or device 1703 (or both) may be a satellite, such as a cubesat or a microsat.

System 1700 may be part of, or may be configured for communication with, a wireless network such as a satellite network, a cellular network or a noncellular network. A satellite network can include, for example, a Low Earth Orbit (LEO) satellite network, a Geostationary (GEO) satellite network or a Medium Earth orbit (MEO) satellite network. A noncellular network can include, for example, a local area network (LAN), a wide area network (WAN) or a packet data network. A cellular network (e.g., radio access network) can include, for example, a 3rd Generation Partnership Project (3GPP) Long Term Evolution (LTE), 5th Generation (5G) New Radio, or Internet-of-Things (IoT) network. A network may include network devices, such as routing apparatuses, network routers or network switches (not shown). Device 1701 and device 1703 may be configured to use or interface with one or more communication protocols, for example, Digital Video Broadcasting-Satellite (DVB-S) protocol, Consultative Committee for Space Data Systems (CCSDS) protocol, Transmission Control Protocol/Internet Protocol (TCP/IP), Institute of Electrical and Electronics Engineers (IEEE) protocols, 3GPP, 5G and European Telecommunications Standards Institute (ETSI) protocols.

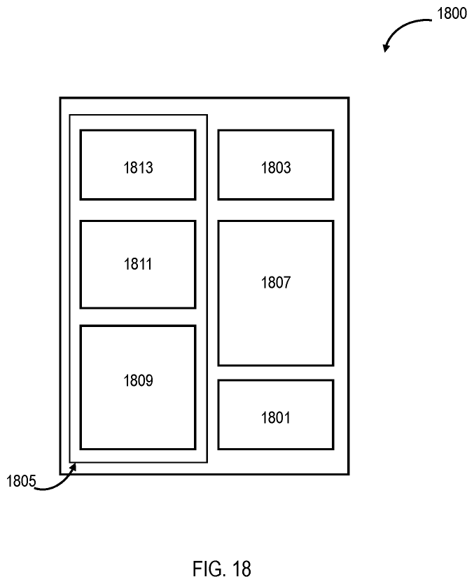

FIG. 18 illustrates a block diagram of an example wireless device 1800, in accordance with some embodiments disclosed herein. Device 1800 may include similar properties and/or elements to device 1701 or device 1703. Aspects may include or operate by logic, components or mechanisms in device 1800. Circuitry may be defined as a collection of circuits implemented in tangible entities of device 1800, including hardware (e.g., simple circuits, gates, logic). Circuitry of device 1800 can include components that are configured to perform the operations of the methods described herein. Circuitry of device 1800 may be hardwired (e.g., hardware circuitry of device 1800) to carry out the operations. Hardware circuitry of device 1800 may include communicatively coupled physical components (e.g., execution components, transistors, simple circuits) including a machine-readable or computer-readable medium that may be physically modified (e.g., magnetically, electrically) to encode instructions of the operations.

In one aspect, device 1800 is a satellite (e.g., cubesat, microsat), for example, within a satellite communication network. Device 1800 may comprise energy block 1801, which may comprise one or more solar cells and a battery, a waste heat radiator 1803, a control-communications block 1805, and a payload 1807. Device 1800 may include additional components which are not shown. In some examples, the payload 1807 may include sensing, measurement or imaging instrumentation. The control-communications block 1805 may comprise a transmitter 1809, a receiver 1811, and control circuitry 1813 (e.g., for managing control functions of the components of device 1800). The components of the device 1800 may be communicatively coupled via an interlink (e.g., bus).

Transmitter 1809 may be an RF or microwave transmitter, including transmitting circuitry configured to be communicatively coupled to one or more antennas, for transmitting RF or microwave signals over a wireless link to another device (e.g., another satellite, ground station). Receiver 1811 may be an RF or microwave receiver, including receiving circuitry configured to be communicatively coupled to one or more antennas, for receiving RF or microwave signals over a wireless link from another device (e.g., ground station or another satellite). In some examples, transmitter 1809 may comprise a MMIC chip. Transmitter 1809 (or receiver 1811) may include circuitry or components comprising substrates similar to substrate 105, substrate 203, substrate 1312, substrate 1314, substrate 1503, or other substrates manufactured according to the methods described herein.

Such substrates contribute to efficient thermal management and improved PAE of the device 1800. Energy consumption (e.g., subsequent heat dissipation) of transmitter 1809 may increase with a data transfer rate according to the Shannon-Hartley theorem. A minimum size of device 1800 may be determined by dimensions of transmitter 1809 and whether device 1800 can produce sufficient power to operate the transmitter 1809. This in turn can be a determining factor in a link budget. For example, power dissipated in the transmitter 1809 may be greater than a sum of powers dissipated in the control circuitry 1813 and the receiver 1811 combined, particularly if the device 1800 is configured to communicate in a high-frequency band (e.g., mmWave, K-band).

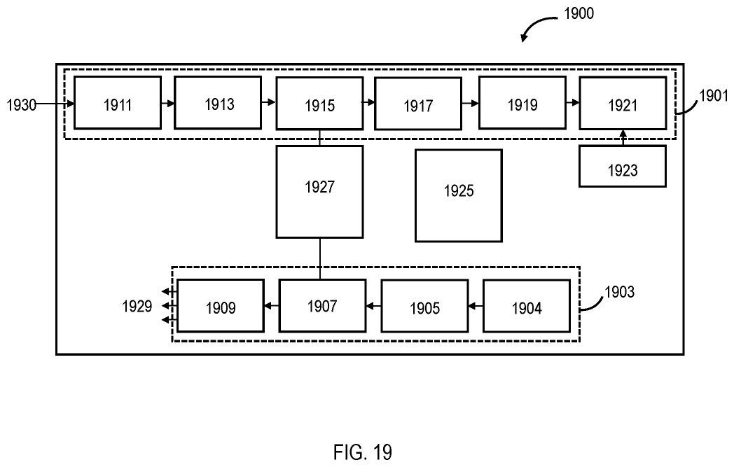

FIG. 19 illustrates a block diagram of an example control-communications block 1900 of a wireless device, in accordance with some embodiments disclosed herein. Control-communications block 1900 may include similar properties and/or elements to control-communications block 1805, and may include additional components not shown in FIG. 19. Control-communications block 1900 may include circuitry or components comprising substrates similar to substrate 300, 900, 1100, or other substrates manufactured according to the methods described herein. Control-communications block 1900 may include transmitting circuitry (e.g., transmitting circuitry 1901), configured to be communicatively coupled to one or more antennas, for transmitting RF or microwave signals. Control-communications block 1900 may also include receiving circuitry (e.g., receiving circuitry 1903) configured to be communicatively coupled to one or more antennas, for receiving RF or microwave signals. In some examples, the receiving circuitry 1903 may comprise a radio front end of a device, such as device 1800.

The receiving circuitry 1903 can include a low-noise amplifier (LNA) 1904, a bandpass filter 1905, a frequency downconverter 1907, and a demodulator 1909. The output of the receiving circuitry 1929 may be transmitted to a modulator or an on-board computer (OBC) (not shown). In some examples, the receiving circuitry 1903 may have additional components, not shown in FIG. 19. The transmitting circuitry 1901 can include a modulator 1911, a low-pass filter (e.g., anti-aliasing filter (AAF)) 1913, a mixer 415, a bandpass filter 417, a variable gain amplifier 1919 (e.g., including a gain-commanding function), and a power amplifier (e.g., solid-state power amplifier SSPA) 1921. In some examples, the transmitting circuitry 401 may have additional components not shown in FIG. 19. Control-communications block 1900 may also include a sequence generator 1923, DC power conditioning circuitry 1925 and frequency synthesis circuitry 1927, which may include a local oscillator (LO) or LO function. Some or all of the components shown in control-communications block 1900 (including those not shown) may communicate with each other via an interlink (e.g., bus) (not shown).

In some examples, the receiving circuitry 1903 may receive an RF signal (e.g., from an antenna of the device 1800). The received RF signal may be transmitted from a ground station or another device (e.g., satellite). The LNA 1904 may amplify the received RF signal, the bandpass filter 1905 may filter the signal to a frequency of interest, the frequency downconverter 1907 may downconvert the filtered RF signal to another frequency (e.g., as used by the frequency synthesis circuitry 1927) for processing of the signal (e.g., removing an RF carrier wave signal to produce an intermediate frequency (IF) signal for processing), and the demodulator 1909 may decode the down-converted signal to extract an information-bearing signal.

In some examples, the transmitting circuitry 1901 may prepare a signal (e.g., RF signal, satellite signal) for transmission to another device (e.g., satellite, ground station). The modulator 1911 may produce an analog baseband information signal from a digital information signal (e.g., provided by another component and input at 1930). The low-pass filter or AAF 1913 may filter the analog signal to remove aliasing from the digital-to-analog conversion. The mixer 1915 may prepare the signal for transmission on an RF carrier wave by mixing the analog baseband signal with an RF signal, for example, an RF signal provided by the frequency synthesis circuitry 1927. The bandpass filter 1917 may filter the resulting RF information signal to a transmission frequency of interest and variable gain amplifier 1919 may provide the RF information signal at a specified gain to an input of the SSPA 1921. The SSPA 1921 may amplify the RF information signal for transmission by one or more antennas of the device (e.g., device 1800). In some examples, the SSPA 1921 may comprise a MMIC chip, similar to MMIC chip 1102. The sequence generator 1923 may generate sequences for the input of the SSPA 1921. For example, the sequence generator 1923 may generate a sequence (e.g., at a specified voltage) for the gate terminal of the MMIC chip and a sequence for the drain terminal of the MMIC chip. DC power conditioning circuitry 1925 may convert a battery supply voltage (e.g., a voltage provided by energy block 1801) to a bias voltage for the components of the control-communications block 1900.

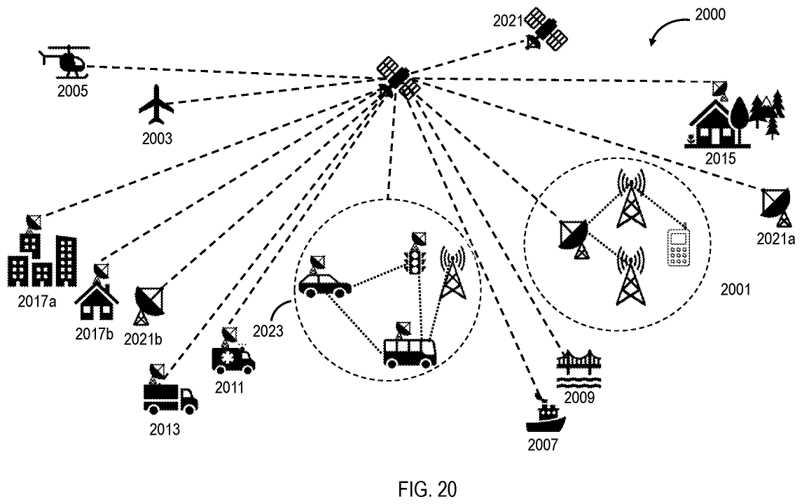

FIG. 20 illustrates a block diagram representing various example wireless communication networks 2000, in accordance with some embodiments disclosed herein. In some examples, FIG. 20 illustrates various applications of devices that comprise circuitry or components comprising substrates similar to substrate 105, substrate 203, substrate 1312, substrate 1314, substrate 1503, or other substrates manufactured according to the methods described herein. Such devices may operate with greater thermal efficiency and power added efficiency (PAE) in comparison to alternative devices that do not include such substrates. Such devices can provide improved RF performance and increased network capacity compared to alternative devices, while reducing a need for complex thermal control systems. Applications of such devices can include, but are not limited to, cellular backhaul over satellite 2001, aeronautical satellite communications (e.g., internet over satellite for aviation 2003, emergency and safety 2005), maritime satellite communications 2007, infrastructure monitoring 2009, land-based emergency and disaster relief 2011, highly-distributed networks 2013 (e.g., asset tracking), network connectivity alternatives for remote areas 2015 or urban areas 2017a and 2017b, satellite communications (e.g. satellite to satellite 2021 and ground station to satellite 2025a and 2025b), and IoT networks 2023. FIG. 20 does not fully illustrate each and every network link or device within each of the aforementioned wireless communication network applications. For each application, additional wireless and/or wired links and devices may be present in a network.

The devices described herein (e.g., 1701, 1703) may be satellite communications devices (e.g., satellites) capable of operating at many different frequencies and communication bands as part of a satellite communication system. For example, such devices may operate in an L-band frequency range (e.g., 1-2 GHz), S-band frequency range (e.g., 2-4 GHz), C-band frequency range (e.g., 4-8 GHz), X-band frequency range (e.g., 8-12 GHz), K-band frequency range (e.g., 17-20 GHz (Ku/K-bands), 37-40 GHz (Ka-bands)), a V-band frequency range (e.g., 40-75 GHz), W-band frequency range (e.g., 75-110 GHz), mm-wave band frequency range, G-band frequency range (e.g., 110-300 GHz), E-band frequency range (e.g., 60-90 GHz), or other frequency ranges.

In some examples, a device is a satellite that may be configured to operate in a Ka-band at a frequency in a range from about 18.3 GHz to about 20.2 GHz (e.g, 18.3 GHz). The satellite may be positioned, as part of a satellite constellation, at an altitude between about 400 km and about 600 km (e.g., 500 km). The satellite may transmit communications signals at an RF power of about 10 W, 20 W or 50 W (e.g., 10 W) and may have a noise power ratio between about 15 dB to about 30 dB (e.g., 30 dB). At least one antenna may be communicatively coupled to the satellite. The antenna may have a cross-polarization isolation (XPI) of 22 dB. The antenna may have a diameter in a range from about 0.45 meters to about 1.2 meters (e.g., 0.5 meters). The antenna may have a diameter in a range from about 2 meters to about 5 meters. The antenna may have an efficiency of about 0.45. The antenna may have a gain of about 36.16 dBi. Antenna gain may be influenced by factors such as antenna efficiency, antenna diameter and the wavelength of the transmitted signal. The pointing error may be about 1.0 degrees. For these values, the transmitter may transmit with an EIRP of about 43.88 dBW.

While preferred examples of the present disclosure have been shown and described herein, it will be obvious to those skilled in the art that such examples are provided by way of example only. It is not intended that the present disclosure be limited by the specific examples provided within the specification. While the present disclosure has been described with reference to the aforementioned specification, the descriptions and illustrations of the examples herein are not meant to be construed in a limiting sense. Numerous variations, changes, and substitutions will now occur to those skilled in the art without departing from the present disclosure. Furthermore, it shall be understood that all examples of the present disclosure are not limited to the specific depictions, configurations or relative proportions set forth herein which depend upon a variety of conditions and variables. It should be understood that various alternatives to the examples of the present disclosure described herein may be employed in practicing the present disclosure. It is therefore contemplated that the present disclosure shall also cover any such alternatives, modifications, variations or equivalents. It is intended that the following claims define the scope of the present disclosure and that methods and structures within the scope of these claims and their equivalents be covered thereby.

1. A device for transmitting or receiving signals, comprising:
a substrate comprising a material having an average value of thermal conductivity equal to or greater than about 1000 W/mK;
at least one transistor comprising a material layer and operably connected to the substrate; and
a feature disposed within at least a portion of the substrate, the feature having an average etch angle, as measured between a surface of the substrate and a sidewall of the feature,
wherein the feature comprises an aspect ratio greater than or equal to about 1.25:1.

2. The device of claim 1, wherein the feature is disposed within at least a portion of the material layer.

3. The device of claim 2, wherein the feature is a via.

4. The device of claim 3, wherein the via is configured to couple the transistor to a surface of the substrate through the material layer and the substrate.

5. The device of claim 1, wherein the etch angle is greater than or equal to about 80 degrees.

6. The device of claim 5, wherein the etch angle is from about 86 degrees to about 90 degrees.

7. The device of claim 1, wherein the feature comprises an aspect ratio greater than or equal to about 5:1.

8. The device of claim 1, wherein the material layer comprises a wide-bandgap semiconductor material.

9. The device of claim 1, wherein the transistor is a high electron mobility transistor.

10. The device of claim 1, wherein the device is a radiofrequency amplifier module.

11. The device of claim 10, wherein the device is a satellite transmitter.

12. A method of generating a feature in a structure comprising a substrate, wherein the substrate comprises a material having an average value of thermal conductivity equal to or greater than about 1000 W/mK, the method comprising:
providing the structure; and
etching the substrate to remove at least a portion of the substrate, wherein the removal of the at least a portion of the substrate exposes a hollow region within the structure having an average etch angle, as measured between a surface of the structure and a sidewall of the hollow region.

13. The method of claim 12, wherein the structure comprises a semiconductor-containing material, and wherein the method further comprises etching a surface within the hollow region to remove at least a portion of the semiconductor-containing material.

14. The method of claim 12, further comprising applying a laser to generate a modified region within the structure, the modified region comprising a modified crystalline structure of the structure at a plurality of focal depths from a surface of the structure, wherein the etching the substrate comprises removal of at least a portion of the modified region, and wherein the removal of the at least a portion of the modified region exposes the hollow region within the structure.

15. The method of claim 14, wherein the structure comprises an etch mask disposed over at least a portion of the surface of the structure, and wherein the method further comprises applying the laser within an opening of the etch mask to generate the modified region within the structure.

16. The method of claim 15, wherein the structure comprises a metal pad disposed on a second surface of the structure, and wherein the method further comprises applying the laser such that the metal pad substantially overlaps, from the second surface, the modified region to be generated.

17. The method of claim 12, wherein the etching comprises plasma etching.

18. The method of claim 12, wherein the etching comprises an etch selectivity within a range from about 10:1 to about 50:1.

19. The method of claim 12, wherein the applying the laser comprises a laser power within a range from about 5 W to about 7 W.

20. The method of claim 12, wherein the hollow region comprises an aspect ratio greater than or equal to about 1.25:1.

21. The method of claim 20, wherein the hollow region comprises an aspect ratio greater than or equal to about 5:1.

22. The method of claim 12, wherein the etch angle is greater than or equal to about 80 degrees.

23. The method of claim 22, wherein the etch angle is within a range from about 86 degrees to about 90 degrees.

24.-110. (canceled)
